(19) United States
(12) Patent Application Publication
(10) Pub. No.: US 2026/0206309 A1
(43) Pub. Date: Jul. 16, 2026

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: MING-HENG TSAI, TAIPEI CITY (TW); TA-CHUN LIN, HSINCHU (TW); JHON JHY LIAW, HSINCHU COUNTY (TW)

(21) Appl. No.: 19/021,214

(22) Filed: Jan. 15, 2025

(51) Int. Cl. H10D 84/85; H10D 30/00; H10D 30/01; H10D 30/43; H10D 62/10; H10D 62/13; H10D 64/23; H10D 64/27; H10D 84/01

(52) U.S. Cl. CPC H10D 84/856; H10D 30/014; H10D 30/019; H10D 30/43; H10D 30/501; H10D 62/121; H10D 62/151; H10D 64/254; H10D 64/514; H10D 64/518; H10D 84/017; H10D 84/0179; H10D 84/0181; H10D 84/0186; H10D 84/851

(57) ABSTRACT

A semiconductor structure includes a substrate, a first device, a second device, a first contact structure and a second contact structure. The first device includes a first gate structure and a first source/drain structure, and the second device includes a second gate structure and a second source/drain structure. The first contact structure penetrates the substrate from a back side and is coupled to the first source/drain structure. The second contact structures penetrates the substrate from the back side and is coupled to the second source/drain structure. A contacted poly pitch of the second gate structure is greater than a contacted poly pitch of the first gate structure, and a depth of the first contact structure is greater than a depth of the second contact structure.

### BACKGROUND

The current trend of miniaturizing integrated circuits (ICs) has resulted in smaller devices which consume less power but provide more functionality at higher speeds. When horizontal routing tracks parallel to power rails are designed for connecting to various gate terminals, source terminals, and drain terminals of transistors in a cell structure, a number of the horizontal routing tracks available for such connections is limited. In addition, the locations of via connectors for connecting the horizontal routing tracks to various the gate terminals, source terminals, and drain terminals of the transistors in the cell structure are also subject to design rule restrictions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart representing a method for forming a semiconductor structure according to aspects of the present disclosure.

FIGS. 2 to 12 are cross-sectional views of a semiconductor structure at various fabrication stages in accordance with aspects of one or more embodiments of the present disclosure.

FIG. 13A is a cross-sectional view of a semiconductor structure in accordance with aspects of one or more embodiments of the present disclosure, FIG. 13B is a schematic layout structure from a top view of the semiconductor structure of FIG. 13A, and FIG. 13C is a schematic layout structure from a bottom view of the semiconductor structure of FIG. 13A.

FIG. 14A is a cross-sectional view of a semiconductor structure in accordance with aspects of one or more embodiments of the present disclosure, FIG. 14B is a schematic layout structure from a top view of the semiconductor structure of FIG. 14A, and FIG. 14C is a schematic layout structure from a bottom view of the semiconductor structure of FIG. 14A.

FIG. 15A is a cross-sectional view of a semiconductor structure in accordance with aspects of one or more embodiments of the present disclosure, FIG. 15B is a schematic layout structure from a top view of the semiconductor structure of FIG. 15A, and FIG. 15C is a schematic layout structure from a bottom view of the semiconductor structure of FIG. 15A.

FIG. 16 is a cross-sectional view of a semiconductor structure in accordance with aspects of one or more embodiments of the present disclosure.

FIG. 17 is a cross-sectional view of a semiconductor structure in accordance with aspects of one or more embodiments of the present disclosure.

FIGS. 18A to 18C are cross-sectional views of a semiconductor structure at a fabrication stage in accordance with aspects of one or more embodiments of the present disclosure.

FIGS. 19A to 19C are cross-sectional views of the semiconductor structure at a fabrication stage subsequent to that of FIGS. 18A to 18C in accordance with aspects of one or more embodiments of the present disclosure.

FIGS. 20A to 20C are cross-sectional views of the semiconductor structure at a fabrication stage subsequent to that of FIGS. 19A to 19C in accordance with aspects of one or more embodiments of the present disclosure.

FIGS. 21A to 21C are cross-sectional views of the semiconductor structure at a fabrication stage subsequent to that of FIGS. 20A to 20C in accordance with aspects of one or more embodiments of the present disclosure.

FIGS. 22A to 22C are cross-sectional views of the semiconductor structure at a fabrication stage subsequent to that of FIGS. 21A to 21C in accordance with aspects of one or more embodiments of the present disclosure.

FIGS. 23A to 23C are cross-sectional views of the semiconductor structure at a fabrication stage subsequent to that of FIGS. 22A to 22C in accordance with aspects of one or more embodiments of the present disclosure.

FIGS. 24A to 24C are cross-sectional views of the semiconductor structure at a fabrication stage subsequent to that of FIGS. 23A to 23C in accordance with aspects of one or more embodiments of the present disclosure.

FIGS. 25A to 25C are cross-sectional views of the semiconductor structure at a fabrication stage subsequent to that of FIGS. 24A to 24C in accordance with aspects of one or more embodiments of the present disclosure.

FIGS. 26A to 26C are cross-sectional views of the semiconductor structure at a fabrication stage subsequent to that of FIGS. 52A to 25C in accordance with aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the embodiments. Accordingly, the disclosure expressly should not be limited to such embodiments illustrating some possible non-limiting combination of features that may exist alone or in other combinations of features; the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The term “nano-structure” refers to atomic, molecular or macromolecular particles typically having a thickness in a range of approximately 1 to 100 nanometers and a width greater than the thickness. For example, the width may be at least twice the thickness, but the disclosure is not limited thereto. Typically, novel and differentiating properties and functions of nanosheet components are observed or developed at a critical length scale of under 100 nm. In some embodiments, “nano-structure” components can also be referred to as “nano-wire,” “nano-sheet,” “nano-slab,” “nano-ring” or “multi-bridge channel” components.

An integrated circuit layout structure can include at least an active region (e.g., an oxide-defined (OD) region) where circuit elements may be formed thereon. Examples of circuit elements include, but are not limited to, transistors and diodes. Examples of transistors include, but are not limited to, metal-oxide-semiconductor field-effect transistors (MOSFET), complementary metal-oxide semiconductor (CMOS) devices, p-channel metal-oxide semiconductors (PMOS), n-channel metal-oxide semiconductors (NMOS), bipolar junction transistors (BJT), high voltage transistors, high frequency transistors, p-channel and/or n-channel field-effect transistors (PFETs/NFETs), FinFETs, planar MOS transistors with raised sources/drains, nanosheet FETs, nanowire FETs, and the like. A contacted poly pitch (CPP) is defined as a minimum distance between two parallel gate structures of FET(s). For example, the CPP may be defined as a center-to-center distance between two immediately adjacent gate structures. As semiconductor technology continues to advance, there is a growing demand for a greater variety and number of transistor devices on a single die in order to achieve integrated functionality among different devices. For example, devices with different CPPs, which are referred to as CPP devices, may be accommodated and integrated.

To provide power or signals to the CPP devices, power rails or power grids are electrically connected to the CPP devices through contact structures. In some comparative approaches, contact structures for the CPP devices may have similar dimensions. In such approaches, a contact resistance between a small CPP device (i.e., a device with a smaller contacted poly pitch) and a contact structure is greater than a contact resistance between a large CPP device (i.e., a device with a larger contacted poly pitch) and the contact structure.

The present disclosure therefore provides a semiconductor structure and a method for forming the same. In some embodiments, a contact structure for small CPP devices has a thickness or a depth greater than that of a contact structure for large CPP devices. In some embodiments, the contact structure for the small CPP devices has a width less than a width of the contact structure for the large CPP devices. Accordingly, a contact resistance of the small CPP devices is reduced, and thus a device performance of the small CPP devices and a device performance of the large CPP devices can be improved concurrently.

In some embodiments, the provided semiconductor structure uses a hybrid power rail (HPR) structure for efficiently providing power to operational components of an IC. In contrast to previous power rail structures that only provide power from one side of a substrate, the HPR structure of the present disclosure allows power to be provided from a front side and a back side of a substrate incorporating the HPR structure.

The embodiments described herein may be employed in design and/or fabrication of any type of integrated circuit, or portion thereof, which may include any of a plurality of various devices and/or components such as a static random-access memory (SRAM) and/or other logic circuits; passive components such as resistors, capacitors, and inductors; active components such as P-channel field-effect transistors (PFETs), N-channel FETs (NFETs), metal-oxide-semiconductor field-effect transistors (MOSFETs), complementary metal-oxide-semiconductor (CMOS) transistors, bipolar transistors, high voltage transistors, high frequency transistors, and strained-semiconductor devices; silicon-on-insulator (SOI) devices; partially-depleted SOI (PD-SOI) devices; fully-depleted SOI (FD-SOI) devices; other memory cells; and other devices known in the art. One of ordinary skill may recognize other embodiments of semiconductor devices and/or circuits, including the design and fabrication thereof, which may benefit from aspects of the present disclosure.

The embodiments described herein may be employed in design and/or fabrication of planar devices and non-planar devices. For example, the embodiments described herein may be employed in design and/or fabrication of multi-gate field-effect transistor (FET) devices, such as Omega-gate (Ω-gate) devices or Pi-gate (H-gate) devices, FinFET devices, gate-all-around (GAA) FET devices, fork sheet FET devices, or complementary MOSFET (CFET) devices that are stacked vertically.

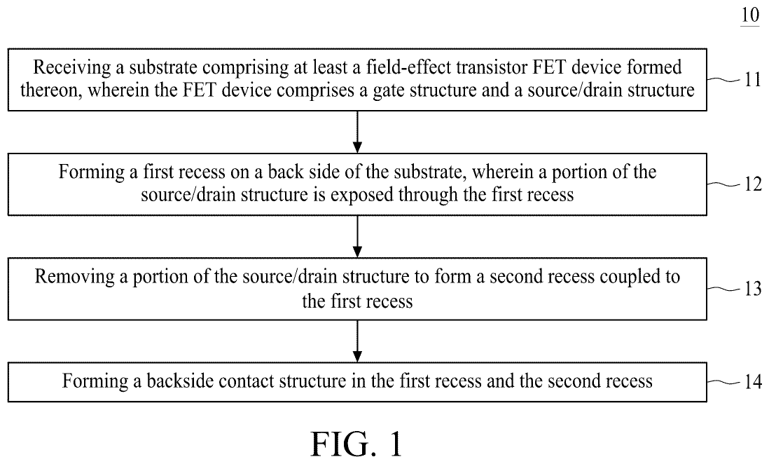

FIG. 1 is a flowchart representing a method for forming a semiconductor structure 10 a ccording to aspects of the present disclosure. The method 10 includes a number of operations (11, 12, 13 and 14). The method 10 will be further described according to one or more embodiments. It should be noted that the operations of the method 10 may be rearranged or otherwise modified within the scope of the various aspects. It should be further noted that additional processes may be provided before, during, and after the method 10, and that some other processes may be briefly described herein. Thus, other implementations are possible within the scope of the various aspects described herein.

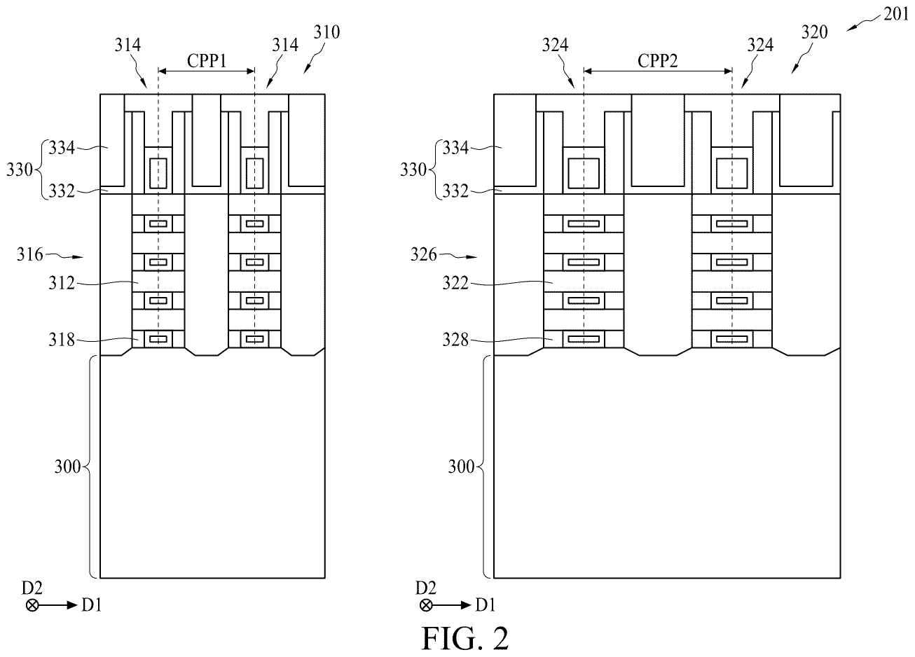

FIGS. 2 to 12 are cross-sectional views of a semiconductor structure at various fabrication stages of the method 10 in accordance with aspects of one or more embodiments of the present disclosure.

Please refer to FIG. 2, which is a cross-sectional view of an intermediate semiconductor structure 201 at a fabrication stage in accordance with aspects of one or more embodiments of the present disclosure. In some embodiments, in operation 11, a substrate 300 including at least a field-effect transistor (FET) device formed thereon is received. In some embodiments, the substrate 300 includes at least a first FET device 310 and a second FET device 320 disposed thereon. In some embodiments, each of the first FET device 310 and the second FET device 320 is a multi-gate FET device such as, for example but not limited thereto, a GAA FET device. Further, the first FET device 310 is separated from the second FET device 320, as shown in FIG. 2. In some embodiments, the first FET device 310 and the second device 320 may be separated from each other by, at least, an isolation structure, such as a shallow trench isolation (STI) structure (not shown). In some embodiments, the STI may include silicon oxide (SiO), silicon nitride (SiN), silicon oxynitride (SiON), fluorine-doped silicate glass (FSG), a low-k dielectric, combinations thereof, and/or other suitable materials known in the art.

In some embodiments, the substrate 300 may be made of elemental semiconductor materials such as crystalline silicon (Si), diamond or germanium (Ge); compound semiconductor materials such as silicon carbide (SiC), gallium arsenic (GaAs), indium arsenide (InAs), or indium phosphide (InP); or alloy semiconductor materials such as silicon germanium (SiGe), silicon germanium carbide (SiGeC), gallium arsenic phosphide (GaAsP), or gallium indium phosphide (GaInP). The substrate 300 may include various layers, including conductive or insulating layers formed on a semiconductor substrate. The substrate 300 may be a bulk silicon substrate, a silicon-on-insulator (SOI) substrate, or a germanium-on-insulator (GOI) substrate. The substrate 300 may also include various doping configurations depending on design requirements, such as different doping profiles for different device types. For example, different doping profiles (e.g., n wells or p wells) may be formed on the substrate 300 designed for different device types (e.g., n-type field-effect transistors (NFET), or p-type field-effect transistors (PFET)). A suitable doping may include ion implantation of dopants and/or diffusion processes. Additionally, the substrate 300 may be doped with p-type impurities or n-type impurities, or may be undoped. In some embodiments, both the first FET device 310 and the second FET device 320 are p-type FET devices, but the disclosure is not limited thereto.

The first FET device 310 includes a plurality of nanostructure channels 312, and the second FET device 320 includes a plurality of nanostructure channels 322. In some embodiments, the nanostructure channels 312 and the nanostructure channels 322 extend in a first direction D1. In some embodiments, the first FET device 310 may include 1, 2, 3, 4 or more than 4 nanostructure channels 312, and the second FET device 320 may include 1, 2, 3, 4 or more than 4 nanostructure channels 322. Further, a quantity of the nanostructure channels 312 is equal to a quantity of the nanostructure channels 322. In some embodiments, a thickness of the nanostructure channel 312 and a thickness of the nanostructure channel 322 may be substantially equal, but the disclosure is not limited thereto. The thickness of the nanostructure channels 312 and 322 is chosen based on device performance considerations. In some embodiments, when the first and second FET devices 310 and 320 are devices of a same conductivity type (i.e., the p-type), the nanostructure channels 312 and the nanostructure channels 322 may include a same material. In such embodiments, the nanostructure channels 312 and the nanostructure channels 322 may be doped with a p-type dopant such as boron (B), aluminum (Al), In, or Ga for forming a p-type channel. In some alternative embodiments, when the first and second FET devices 310 and 320 are n-type devices, the nanostructure channels 312 and the nanostructure channels 322 may be doped with an n-type dopant such as P, As, or Sb for forming an n-type channel. In some embodiments, a length of the nanostructure channel 312 is different from a length of the nanostructure channel 322. For example, the length of the nanostructure channel 312 is less than the length of the nanostructure channel 322.

The first FET device 310 further includes gate structures 314 wrapped around the nanostructure channels 312 and extending in a second direction D2. The second FET device 320 further includes gate structures 324 wrapped around the nanostructure channels 322 and extending in the second direction D2. As shown in FIG. 2, the second direction D2 is different from the first direction D1. In some embodiments, the gate structures 314 and the gate structures 324 may be metal gate structures. In such embodiments, each of the gate structures 314 and the gate structures 324 includes a high-k gate dielectric layer. In some embodiments, an interfacial layer (IL) may be formed between each of the nanostructure channels 312 and the high-k gate dielectric layer of the metal gate structures 314, and an IL may be formed between each of the nanostructure channels 324 and the high-k gate dielectric layer of the metal gate structures 324. In some embodiments, the high-k gate dielectric layer includes a high-k dielectric material having a high dielectric constant, for example, a dielectric constant greater than that of thermal silicon oxide (~3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOₓN_{y}), other suitable metal-oxides, or a combination thereof.

In some embodiments, the gate structures 314 and the gate structures 324 may be metal gate structures of a same conductivity type. In such embodiments, each of the gate structures 314 and the gate structures 324 includes at least a work function metal layer and a gap-filling layer. The work function metal layer may include one or more metal layers. The work function metal layer may be a p-type or an n-type work function layer depending on the type (PFET or NFET) of the device. The p-type work function layer comprises a metal with a sufficiently large effective work function, selected from but not restricted to the group of titanium nitride (TiN), tantalum nitride (TaN), ruthenium (Ru), molybdenum (Mo), tungsten (W), platinum (Pt), and combinations thereof. The n-type work function layer comprises a metal with sufficiently low effective work function, selected from but not restricted to the group of titanium (Ti), aluminum (Al), tantalum carbide (TaC), tantalum carbide nitride (TaCN), tantalum silicon nitride (TaSiN), titanium silicon nitride (TiSiN), and combinations thereof. The gap-filling metal layer may include Al, W, cobalt (Co), and/or other suitable materials.

Still referring to FIG. 2, a first contacted poly pitch CPP1 is defined between center lines of two adjacent gate structures 314, and a second contacted poly pitch CPP2 is defined between center lines of two adjacent gate structures 324. The first contacted poly pitch CPP1 is smaller than the second contacted poly pitch CPP2. In such embodiments, the first FET device 310 may be referred to as a small CPP device, while the second FET device may be referred to as a large CPP device.

Additionally, in the context of IC design, a “cell” refers to a standardized unit or structure that is selected from a library and used to create a layout of an IC. Cells can include logic blocks and standard cell structures, which may incorporate transistor devices such as fin field-effect transistors (finFETs). The cells are arranged in a routing grid and connected by conductive structures, such as metal lines, to form the IC layout. Design and placement of the cells are carried out by an automatic placement and routing (APR) tool, which includes a placer and a router, to optimize location and routing of the cells according to design rules. In some embodiments, a cell height is determined by a number of horizontal tracks extending between uppermost and lowermost edges of the cell. In some embodiments, the small CPP devices and the large CPP device are disposed in different cells. In such embodiments, a cell height of the cell including the large CPP device is greater than a cell height of the cell including the small CPP device. In some embodiments, a difference between the cell heights may be between approximately 10 nanometers and approximately 100 nanometers, but the disclosure is not limited thereto.

In some embodiments, the nanostructure channels 312 of the first FET device 310 (i.e., the small CPP device) and the nanostructure channels 322 of the second FET device 320 (i.e., the large CPP device) are disposed in different active regions, which are defined by isolation structures. Such active regions may be referred to as oxide-defined (OD) regions. In some embodiments, a width of the OD region accommodating the nanostructure channels 312 of the small CPP device 310 is less than a width of the OD region accommodating the nanostructure channels 322 of the large CPP device 320. In some embodiments, a difference between the widths may be between approximately 5 nanometers and approximately 40 nanometers, but the disclosure is not limited thereto.

Still referring to FIG. 2, the first FET device 310 further includes a source/drain structure 316 disposed at two sides of the gate structures 314, and the second FET device 320 further includes a source/drain structure 326 disposed at two sides of the gate structures 324. In some embodiments, the source/drain structure 316 and the source/drain structure 326 may be epitaxial source/drain structures. The epitaxial source/drain structures may be a source or a drain, individually or collectively depending upon the context. In some embodiments, the epitaxial source/drain structures 316 and 326 are formed by an epitaxial (epi) process. In addition, a lattice constant of a strained material may be different from a lattice constant of the substrate 300. In some embodiments, the epitaxial source/drain structures 316 and 326 serve as stressors that improve carrier mobility. When the epitaxial source/drain structure 316 and 326 are formed for an n-FET, each of the epitaxial source/drain structures 316 and 326 may be a semiconductor epitaxial layer doped with an n-type impurity, such as phosphorus, but the disclosure is not limited thereto. For example, in some embodiments, each of the epitaxial source/drain structures 316 and 326 may include silicon phosphorous (SiP), silicon arsenide (SiAs), silicon germanium arsenide (SiGeAs), or a combination thereof. Other suitable materials for the epitaxial source/drain structures 316 and 326 are within the contemplated scope of the present disclosure. When the epitaxial source/drain structures 316 and 326 are formed for a p-FET, each of the epitaxial source/drain structures 316 and 326 may be a semiconductor epitaxial layer doped with a p-type impurity. For example but not limited thereto, the epitaxial source/drain structures 316 and 326 may be a boron-doped (B-doped) epitaxial layer. In some embodiments, the epitaxial source/drain structures 316 and 326 may include a SiGe/Si stack, SiB, or a combination thereof. Other suitable materials for the epitaxial source/drain structures 316 and 326 are within the contemplated scope of the present disclosure.

Still referring to FIG. 2, in some embodiments, a volume of the source/drain structure 316 is different from a volume of the source/drain structure 326. In some embodiments, when the first FET device 310 is the small CPP device and the second FET device 320 is the large CPP device, the volume of the source/drain structure 316 is less than the volume of the source/drain structure 326. In some embodiments, a difference between a height of the source/drain structure 316 and a height of the source/drain structure 326 in a cross-sectional view taken along the first direction D1 may between approximately 1 nanometer and approximately 10 nanometers. In some embodiments, a difference between a width of the source/drain structure 316 and a width of the source/drain structure 326 in a cross-sectional view taken along the second direction D2 may be between approximately 5 nanometers and approximately 40 nanometers. In such embodiments, a resistance of the large CPP device (i.e., the second FET device 320) having the large-volume source/drain structure 326 is reduced.

Additionally, the first FET device 310 further includes a plurality of inner spacers 318, and the second FET device includes a plurality of inner spacers 328. As shown in FIG. 2, the inner spacers 318 are disposed between the source/drain structure 316 and the gate structure 314, and the inner spacers 328 are disposed between the source/drain structure 326 and the gate structure 324. In some embodiments, each of the inner spacers 318 and 328 includes silicon oxycarbonitride (SiOCN), silicon carbonitride (SiCN), or silicon oxycarbide (SiOC), but the disclosure is not limited thereto.

In some embodiments, a dielectric structure 330 is formed over the substrate 300. Further, the dielectric structure 330 at least laterally surrounds the gate structures 314 and 324. In some embodiments, the dielectric structure 330 includes a contact etch-stop layer (CESL) 332 and an interlayer dielectric (ILD) 334. In some embodiments, the CESL 332 can include silicon nitride (SiN), SiCN, SiOCN, SiOC, and/or other applicable materials. In some embodiments, the ILD 334 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), and polyimide.

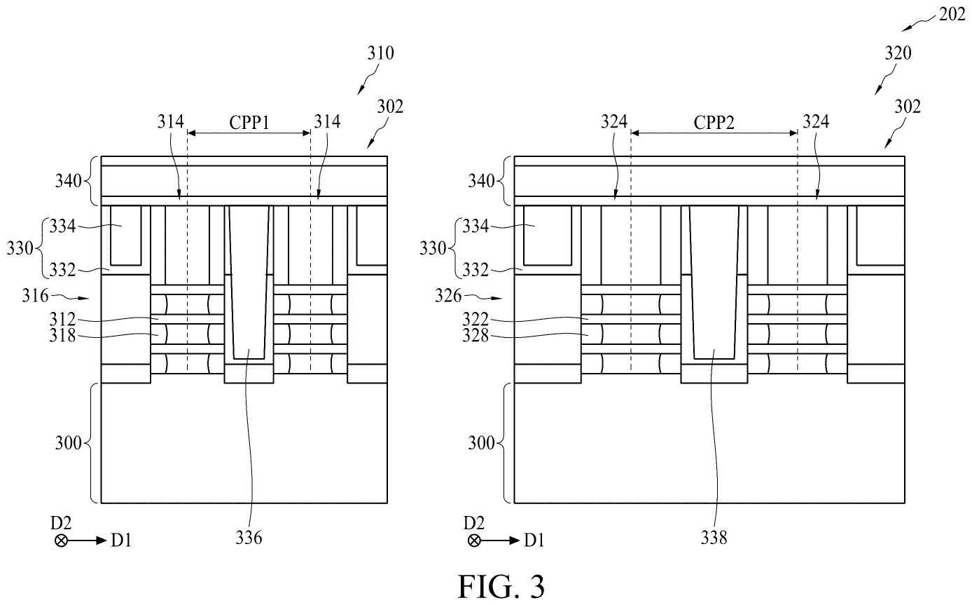

FIG. 3 is a cross-sectional view of an intermediate semiconductor structure 202 at a fabrication stage subsequent to that shown in FIG. 2 in accordance with aspects of one or more embodiments of the present disclosure. In some embodiments, contact structures may be formed to couple to the source/drain structure. For example, a contact structure 336 is formed to couple to the source/drain structure 316 of the first FET device 310, and a contact structure 338 is formed to couple to the source/drain structure 326 of the second FET device 320. As shown in FIG. 3, in some embodiments, the contact structures 336 and 338 are formed by removing a portion of the dielectric structure 330 and a portion of the source/drain structures 316 and 326 from a front side 302 of the substrate 300 to form openings (not shown) and filling the openings with conductive materials. In some embodiments, metal silicide structures may be formed between the contact structure 336 and the source/drain structure 316, and between the contact structure 338 and the source/drain structure 326, though not shown. In some embodiments, a depth of the contact structure 336 and a depth of the contact structure 338 may be the same, but the disclosure is not limited thereto. In some embodiments, a width of the contact structure 336 and a width of the contact structure 338 may be the same, but the disclosure is not limited thereto. In some embodiments, when the contact structure 338 is coupled to the source/drain structure 326 of a large CPP device (i.e., the second FET device 320) and the contact structure 336 is coupled to the source/drain structure 316 of a small CPP device (i.e., the first FET device 310), the width of the contact structure 336 is less than the width of the contact structure 338.

Still referring to FIG. 3, in some embodiments, another dielectric structure 340 may be formed over the substrate 300 on the front side 302. The dielectric structure 340 may be a multi-layered structure, but the disclosure is not limited thereto.

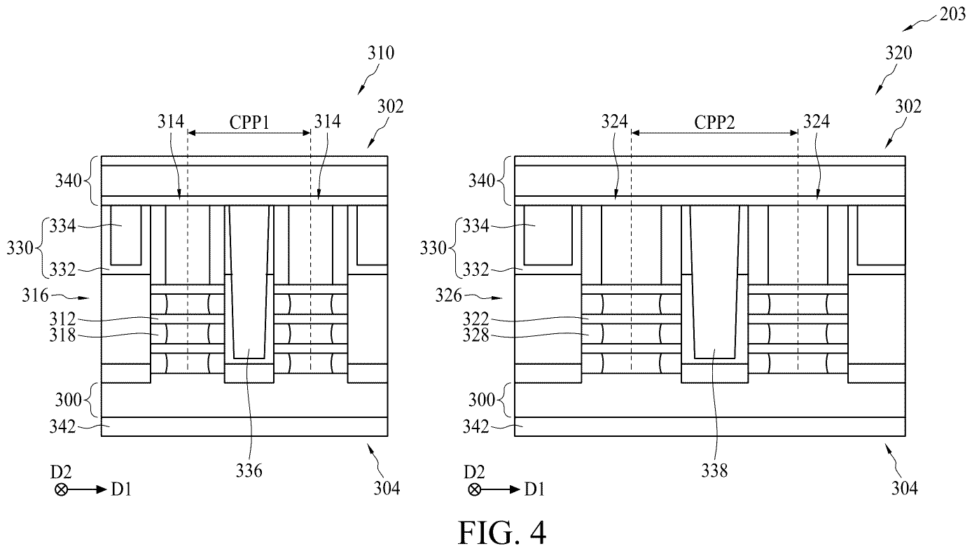

In some embodiments, in operation 12, a first recess is formed on a back side 304 of the substrate 300. In some embodiments, operation 12 may include further operations. Please refer to FIG. 4, which is a cross-sectional view of an intermediate semiconductor structure 203 at a fabrication stage subsequent to that shown in FIG. 3 in accordance with aspects of one or more embodiments of the present disclosure. In some embodiments, a portion of the substrate 300 is removed from the back side 304. In some embodiments, the removal of the portion of the substrate 300 may be referred to as a wafer thinning operation. In some embodiments, the removal of the portion of the substrate 300 may include a planarization such as a chemical mechanical polishing (CMP), but the disclosure is not limited thereto.

Still referring to FIG. 4, in some embodiments, a dielectric layer 342 is formed over the substrate 300 on the back side 304. In some embodiments, the dielectric layer 342 includes a single-layered structure or a multi-layered structure. In some embodiments, the dielectric layer 342 includes SiN, silicon oxide (SiO), silicon oxynitride (SiON), SiCN, SiOCN, SiCO, or a high-k dielectric material (e.g., HfO, AlO, etc.), but the disclosure is not limited thereto. The dielectric layer 342 may serve as a bottom isolation for mitigating a bottom leakage issue.

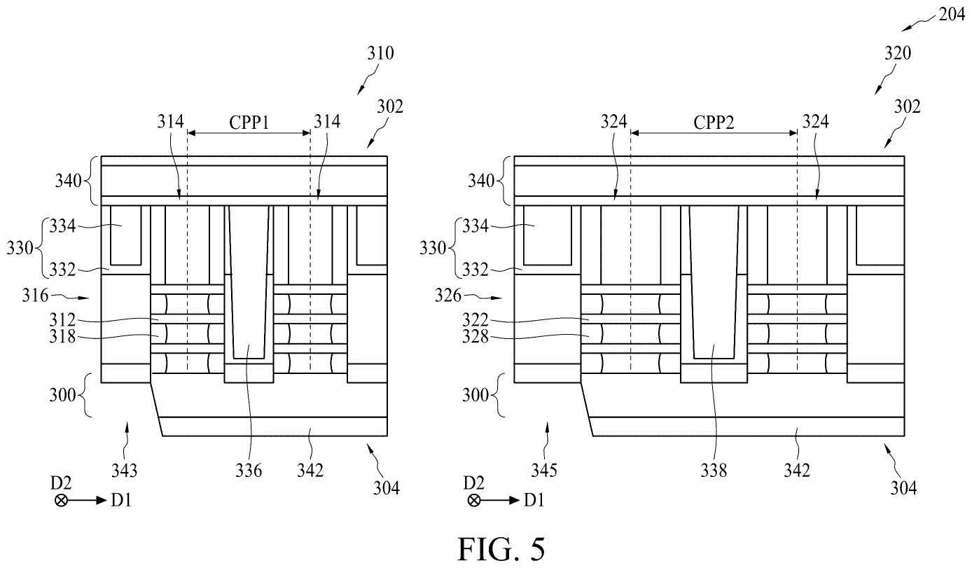

Please refer to FIG. 5, which is a cross-sectional view of an intermediate semiconductor structure 204 at a fabrication stage subsequent to that shown in FIG. 4 in accordance with aspects of one or more embodiments of the present disclosure. In some embodiments, a patterned mask (not shown) may be formed over the substrate 300 on the back side 304. Subsequently, an etch operation is performed to remove portions of the dielectric layer 342 and portions of the substrate 300 from the back side 304. Accordingly, recesses 343 and 345 are formed. As shown in FIG. 5, a portion of the source/drain structure 316 is exposed through the recess 343 on the back side 304, and a portion of the source/drain structure 326 is exposed though the recess 345 on the back side 304. In some embodiments, a depth of the recess 343 is equal to a depth of the recess 345. In some embodiments, a width of the recess 343 is equal to a width of the recess 345. In some embodiments, when the source/drain structure 328 has a greater volume, as in a large CPP device (i.e., the second FET device 320), the width of the recess 345 may be greater than the width of the recess 343.

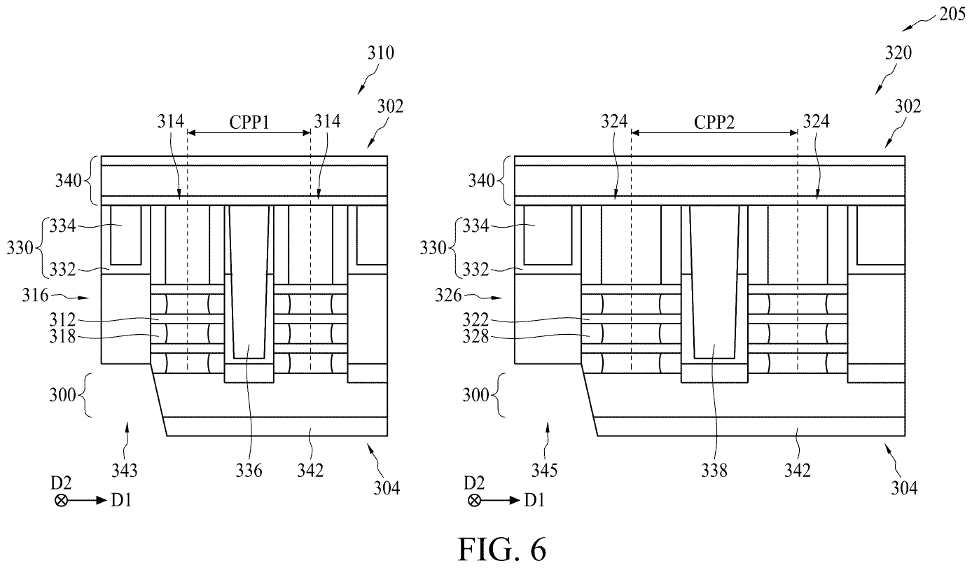

Please refer to FIG. 6, which is a cross-sectional view of an intermediate semiconductor structure 205 at a fabrication stage subsequent to that shown in FIG. 5 in accordance with aspects of one or more embodiments of the present disclosure. In some embodiments, a portion of the source/drain structure 316 exposed through the recess 343 is removed, and a portion of the source/drain structure 326 exposed through the recess 345 is removed. For example, when the source/drain structures 316 and 326 include an epitaxial layer that includes non-doped semiconductor material, such epitaxial layers of the source/drain structure 316 and the source/drain structure 326 are removed.

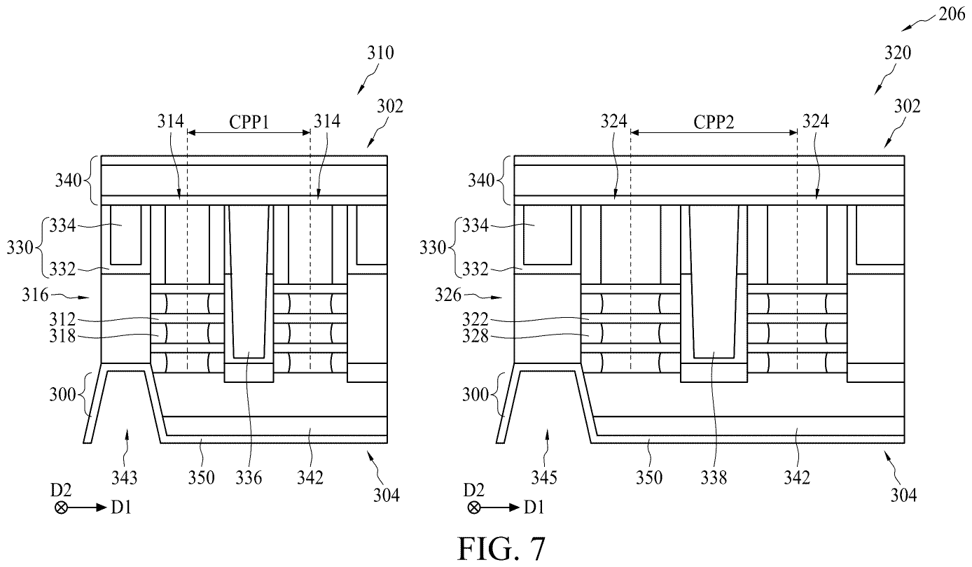

Please refer to FIG. 7, which is a cross-sectional view of an intermediate semiconductor structure 206 at a fabrication stage subsequent to that shown in FIG. 6 in accordance with aspects of one or more embodiments of the present disclosure. In some embodiments, a dielectric layer 350 may be formed over the substrate 300 on the back side 304. The dielectric layer 350 covers sidewalls of the recess 343, sidewalls of the recess 345, and the dielectric layer 342. Further, the dielectric layer 350 covers the portion of the source/drain structure 316 exposed through the recess 343 and the portion of the source/drain structure 326 exposed through the recess 345. In some embodiments, the dielectric layer 350 includes SiN. In such embodiments, the dielectric layer 350 may be referred to as a silicon nitride re-deposition (SNR) layer, but the disclosure is not limited thereto.

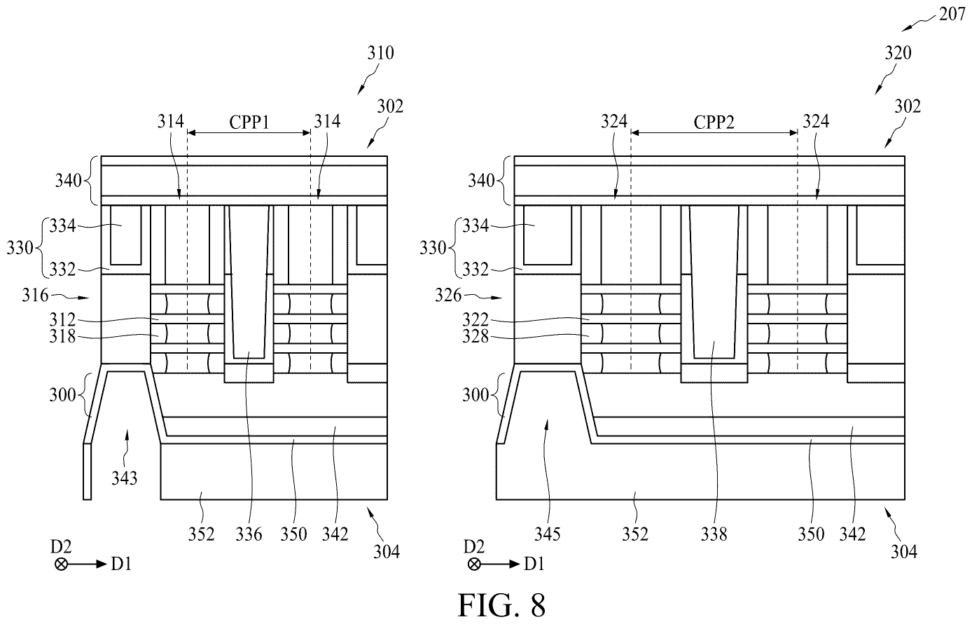

Please refer to FIG. 8, which is a cross-sectional view of an intermediate semiconductor structure 207 at a fabrication stage subsequent to that shown in FIG. 7 in accordance with aspects of one or more embodiments of the present disclosure. In some embodiments, a protection layer 352 is formed to fill the recess 345 and to cover a portion of the dielectric layer 350 in an area where the large CPP device (i.e., the second FET device 320) is located. In some embodiments, the protection layer 352 may include a photoresist and/or a bottom anti-reflective coating (BARC), but the disclosure is not limited thereto.

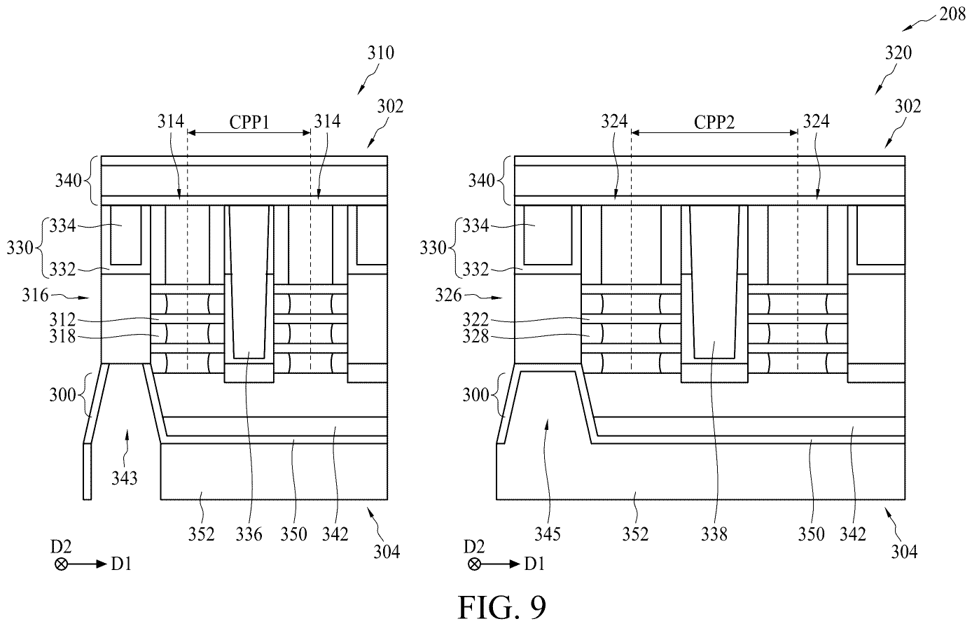

Please refer to FIG. 9, which is a cross-sectional view of an intermediate semiconductor structure 208 at a fabrication stage subsequent to that shown in FIG. 8 in accordance with aspects of one or more embodiments of the present disclosure. In some embodiments, the protection layer 352 may serve as a mask layer in an etch operation. For example, in some embodiments, a portion of the dielectric layer 350 exposed through the mask layer (i.e., the protection layer 352) is removed by the etch operation. Consequently, the source/drain structure 316 is exposed through the recess 343 again.

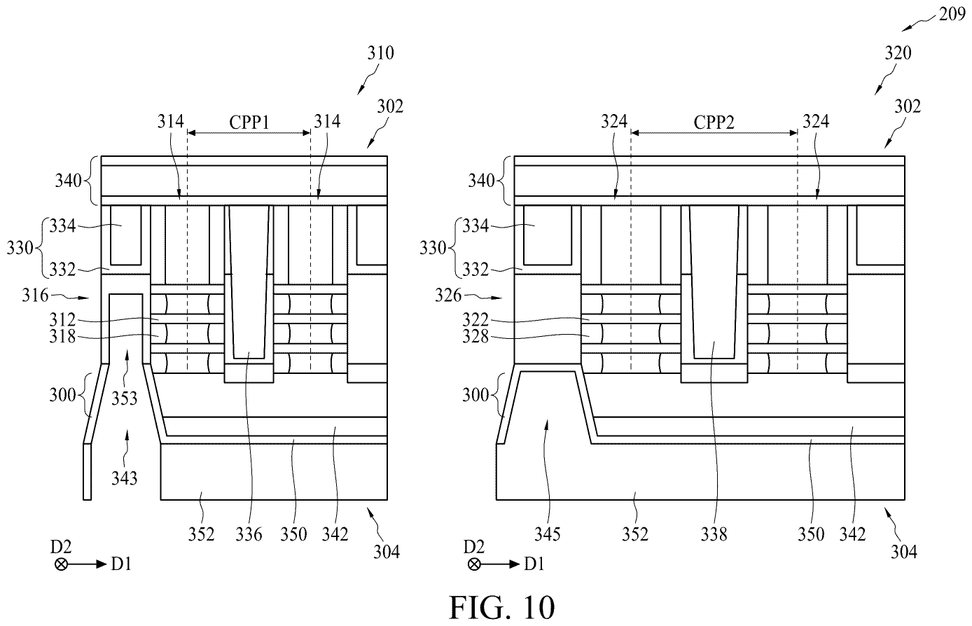

In some embodiments, in operation 13, a portion of the source/drain structure 316 exposed through the recess 343 is removed. Please refer to FIG. 10, which is a cross-sectional view of an intermediate semiconductor structure 209 at a fabrication stage subsequent to that shown in FIG. 9 in accordance with aspects of one or more embodiments of the present disclosure. In some embodiments, the portion of the source/drain structure 316 exposed through the recess 343 is removed such that a recess 353 is formed. As shown in FIG. 10, the recess 353 is coupled to the recess 343. In some embodiments, the remaining source/drain structure 316 may have a first surface facing the front side 302, and a second surface facing the back side 304 and exposed through the recess 353. In some embodiments, the second surface of the remaining source/drain structure 316 is lower than a topmost nanostructure channel 312.

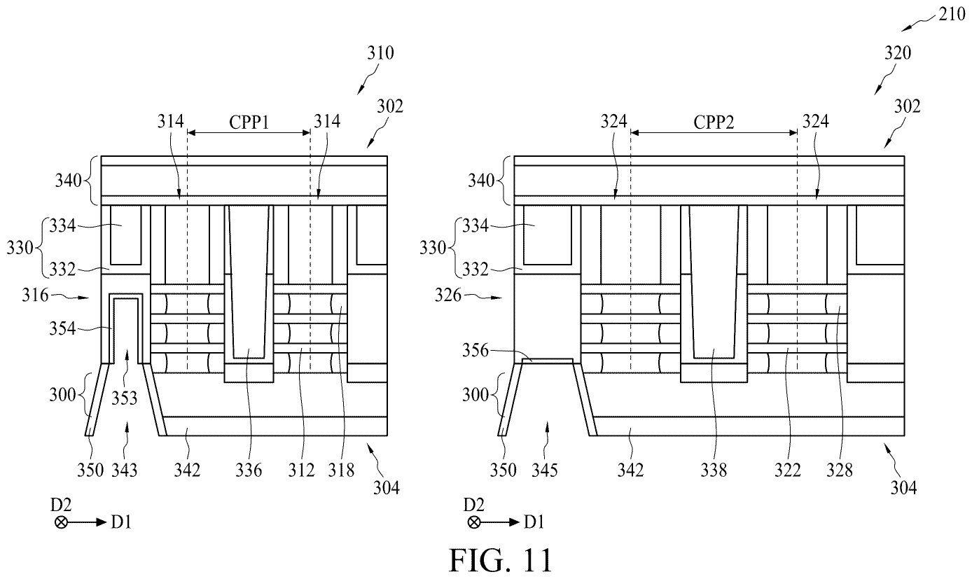

In some embodiments, in operation 14, a contact structure is formed in the recesses. In some embodiments, operation 14 includes further operations. Please refer to FIG. 11, which is a cross-sectional view of an intermediate semiconductor structure 210 at a fabrication stage subsequent to that shown in FIG. 10 in accordance with aspects of one or more embodiments of the present disclosure. In some embodiments, the protection layer 352 is removed, and a portion of the dielectric layer 350 is subsequently removed, thereby exposing a portion of the source/drain structure 326 through the recess 345. In some embodiments, metal silicide structures 354 and 356 are formed. As shown in FIG. 11, the metal silicide structure 354 is formed over surfaces of the source/drain structure 316 exposed through the recess 353, and the metal silicide structure 356 is formed over a surface of the source/drain structure 326 exposed through the recess 345. In some embodiments, the metal silicide structures 354 and 356 include titanium silicide (TiSi), zirconium (Zr) dipole, molybdenum silicide (MoSi) or ruthenium silicide (RuSi), but the disclosure is not limited thereto. In some embodiments, a configuration of the metal silicide structure 354 is different from a configuration of the metal silicide structure 356. For example but not limited thereto, the metal silicide structure 354 has a U-shaped (or an inverted U-shaped) configuration, while the metal silicide structure 356 has a flat configuration.

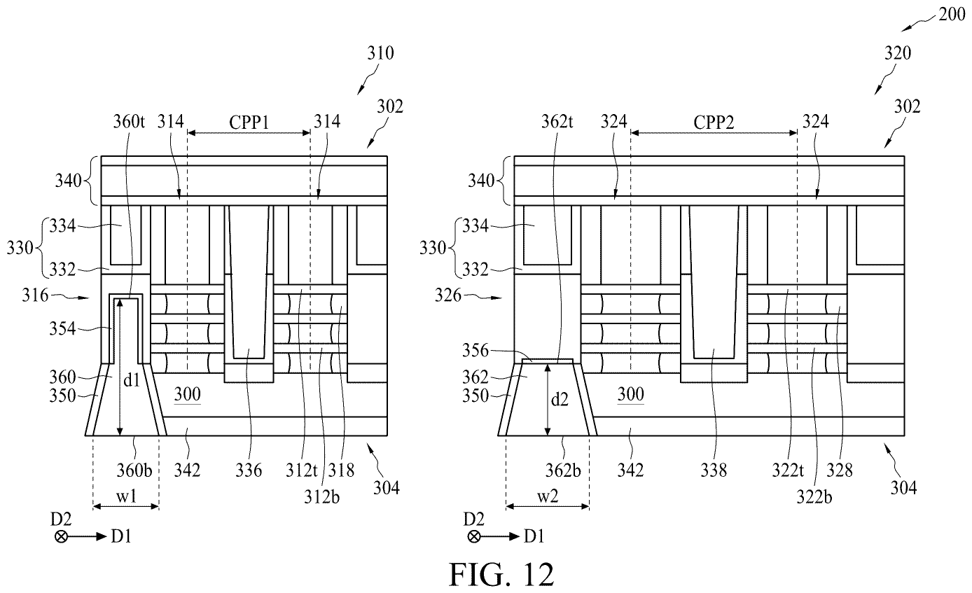

Please refer to FIG. 12, which FIG. 12 is a cross-sectional view of a semiconductor structure 200 at a fabrication stage subsequent to that shown in FIG. 11 in accordance with aspects of one or more embodiments of the present disclosure. In some embodiments, a backside contact structure 360 is formed in the recesses 343 and 353, and a backside contact structure 362 is formed in the recess 345. In some embodiments, the backside contact structures 360 and 362 include a same material. In some embodiments, the backside contact structures 360 and 362 include tungsten (W), ruthenium (Ru), Mo, cobalt (Co), or a combination thereof. Other suitable materials for the backside contact structures 360 and 362 are within the contemplated scope of the present disclosure.

Accordingly, the semiconductor structure 200 is provided. The semiconductor structure 200 includes a substrate (i.e., the substrate 300), a first device (i.e., the first FET device 310) and a second device (i.e., the second FET device 320). The first device includes a plurality of nanostructure channels, a gate structure, and a source/drain structure. In some embodiments, the nanostructure channels of the first device are similar to the abovementioned nanostructure channels 312, the gate structure of the first device is similar to the abovementioned metal gate structure 314, and the source/drain structure of the first device is similar to the abovementioned source/drain structure 316; therefore repeated descriptions are omitted. The second device includes a plurality of nanostructure channels, a gate structure, and a source/drain structure. In some embodiments, the nanostructure channels of the second device are similar to the abovementioned nanostructure channels 322, the gate structure of the second device is similar to the abovementioned metal gate structure 324, and the source/drain structure of the second device is similar to the abovementioned source/drain structure 326; therefore, repeated descriptions are omitted.

In some embodiments, a width of the gate structure 324 of the second device 320 is greater than a width of the gate structure 314 of the first device 310. In some embodiments, a difference between the width of the gate structure 322 and the width of the gate structure 312 is between approximately 1 nanometer and approximately 4 nanometers, but the disclosure is not limited thereto. In some embodiments, a contacted poly pitch CPP1 of the first device 310 is smaller than a contacted poly pitch CPP2 of the second device 320. In such embodiments, the first device 310 is referred to as a small CPP device 310, and the second device 320 is referred to as a large CPP device 320. In some embodiments, the small CPP device 310 and the large CPP device 320 have a same conductivity. For example, the small CPP device 310 and the large CPP device 320 are both p-type FET devices. However, in some alternative embodiments, the small CPP device 310 and the large CPP device 320 are both n-type FET devices.

Still referring to FIG. 12, the semiconductor structure 200 further includes a backside contact structure 360 and a backside contact structure 362 penetrating through the substrate 300 from a back side 304. The backside contact structure 360 is coupled to the source/drain structure 316, and the backside contact structure 362 is coupled to the source/drain structure 326. In some embodiments, a depth d1 of the backside contact structure 360 is measured from a topmost surface 360t facing the front side 302 to a bottommost surface 360b facing the back side 304, and a depth d2 of the backside contact structure 362 is measured from a topmost surface 362t facing the front side 302 to a bottommost surface 362b facing the back side 304. As shown in FIG. 12, the depth d1 of the backside contact structure 360 is greater than the depth d2 of the backside contact structure 362. In some embodiments, a difference between the depth d1 and the depth d2 may be between approximately 2 nanometers and approximately 25 nanometers, but the disclosure is not limited thereto. In some embodiments, the top surface 360t of the backside contact structure 360 is between a bottommost nanostructure channel 312b and a topmost nanostructure channel 312t. In some embodiments, the top surface 362t of the backside contact structure 362 is lower than a bottommost nanostructure channel 322b. In some embodiments, the bottommost nanostructure channel 322b is between a topmost nanostructure channel 322t and the top surface 362t of the backside contact structure 362. In some embodiments, a width w1 of the backside contact structure 360 is less than a width w2 of the backside contact structure 362. In some embodiments, a difference between the width w2 of the backside contact structure 362 and the width w1 of the backside contact structure 360 is between approximately 1 nanometer and approximately 10 nanometers, but the disclosure is not limited thereto. In some embodiments, the backside contact structure 360 is referred to as a deeper (or taller) structure, and the backside contact structure 362 is referred to as a shallower (or shorter) structure.

In some embodiments, the small CPP device has the deeper backside contact structure 360 while the large CPP device has the shallower contact structure 362. The deeper backside contact structure 360 has more area coupled to the source/drain structure 316, and thus a contact resistance is reduced.

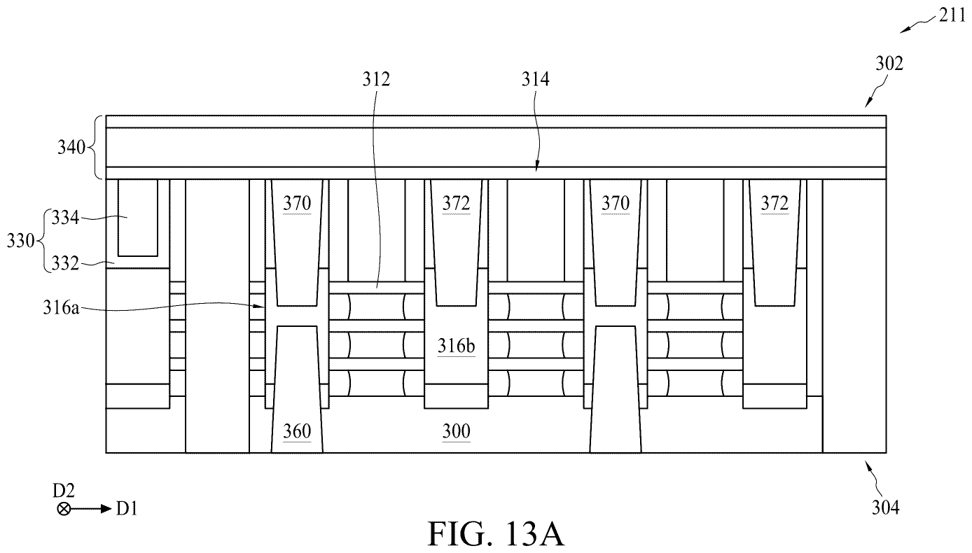

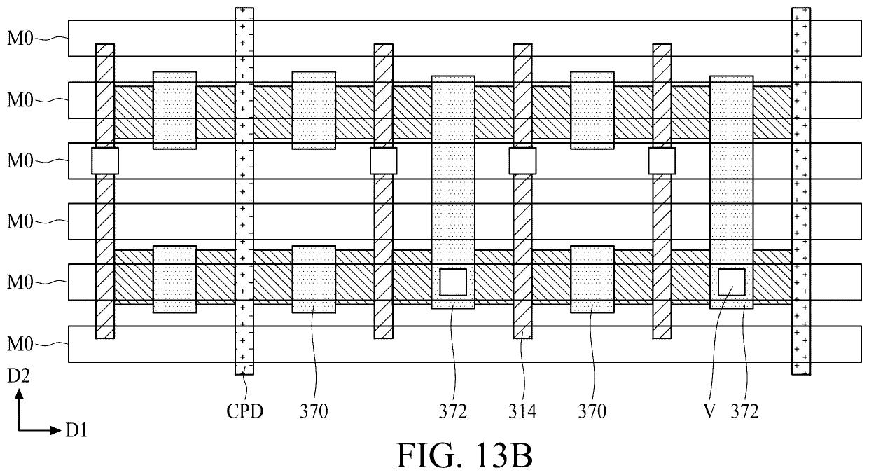

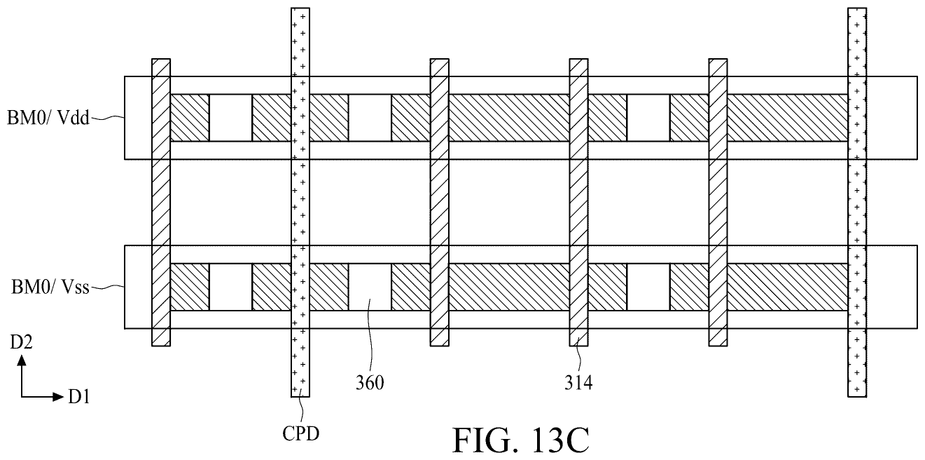

Please refer to FIGS. 13A to 13C, wherein FIG. 13A is cross-sectional view of a semiconductor structure in accordance with aspects of one or more embodiments of the present disclosure, FIG. 13B is a schematic layout structure from a top view of the semiconductor structure of FIG. 13A, and FIG. 13C is a schematic layout structure from a bottom view of the semiconductor structure of FIG. 13A. In some embodiments, the semiconductor structure 211 is provided. The semiconductor structure 211 may be formed using the abovementioned method 10, but the disclosure is not limited thereto. In some embodiments, the semiconductor structure 211 may include a small CPP device and a large CPP device. The small CPP device and the large CPP device may be planar devices or non-planar devices. In some embodiments, when the small CPP device and the large CPP device are non-planar devices, each of the small CPP device and the large CPP device can be a FinFET device or a GAA device. The large CPP device may be similar to the abovementioned second device; therefore, repeated descriptions are omitted. In such embodiments, only the small CPP devices are shown in FIGS. 13A to 13C.

The semiconductor structure 211 includes a substrate 300 having a front side 302 and a back side 304 opposite to the front side 302. The substrate 300 may include materials similar to those described above; therefore, such details are not repeated herein. In some embodiments, the small CPP device of the semiconductor structure 211 is a GAA device. In such embodiments, the small CPP device includes a plurality of nanostructure channels 312 disposed in an OD region (shown in FIGS. 13B and 13C). The small CPP device further includes a gate structure 314 wrapped around the nanostructure channels 312. The gate structure 314 may include layers such as a high-k gate dielectric layer, a work function metal layer and a gap-filling layer that are similar to those described above; therefore, such details are not repeated herein. The nanostructure channels 312 extend in a first direction D1, and the gate structure 314 extends in a second direction D2 different from the first direction D1. The small CPP device further includes source/drain structures 316a and 316b at two sides of the gate structure 314. The source/drain structures 316a and 316b may be a source or a drain, individually or collectively depending upon the context.

In some embodiments, the semiconductor structure 211 further includes a contact structure 370 and a contact structure 372 extending in a direction perpendicular to both the first direction D1 and the second direction D2. The contact structure 370 is coupled to the source/drain structure 316a, and the contact structure 372 is coupled to the source/drain structure 316b. In some embodiments, the contact structure 370 and the contact structure 372 are simultaneously formed. In some embodiments, the contact structure 370 and the contact structure 372 include a same material. In some embodiments, the formation of the contact structures 370 and 372 and materials of the contact structures 370 and 372 are similar to those of the abovementioned contact structures 336 and 338; therefore, repeated descriptions are omitted. In some embodiments, a depth and a width of the contact structure 370 are similar to a depth and a width of the contact structure 372, but the disclosure is not limited thereto. In some embodiments, the depths and the widths of the contact structures 370 and 372 are similar to a depth and a width of a contact structure of the large CPP device, but the disclosure is not limited thereto.

In some embodiments, a dielectric layer 340 may be formed over the contact structures 370 and 372. In some embodiments, the contact structures 370 are enclosed by the dielectric layer 340 and a dielectric structure 330. The dielectric structure 330 may include a contact etch stop layer (CESL) 332 and an inter-layered dielectric (ILD) 334. In some embodiments, the CESL can include silicon nitride (SiN), silicon carbonitride (SiCN), silicon oxycarbonitride (SiOCN), silicon oxycarbide (SiOC), and/or other applicable materials. In some embodiments, The ILD layer 332 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), and polyimide.

In some embodiments, the contact structure 370 is electrically isolated from other devices or elements by the dielectric structure 330 and the dielectric layer 340. In such embodiments, the contact structure 370 serves as a dummy contact structure. In some embodiments, the contact structure 372 is electrically connected to a back-end-of-line (BEOL) line M0 through a via structure V disposed over the front side 302 of the substrate 300, as shown in FIG. 13B. In some embodiments, the metal lines M0 are signal lines.

Still referring to FIGS. 13A to 13C, in some embodiments, the semiconductor structure 211 includes a backside contact structure 360 extending into the semiconductor substrate 211 from the back side 304 in the direction perpendicular to the first and second directions D1 and D2. Further, the backside contact structure 360 is coupled to the source/drain structure 316a. In such embodiments, the source/drain structure 316a is coupled to the contact structure 370, which extended from the front side 302, and coupled to the backside contact structure 360, which extended from on the back side 304. In such embodiments, the contact structure 370 overlaps the backside contact structure 360. Further, the contact structure 370 and the backside contact structure 360 are separated from each other by the source/drain structure 316a. In some embodiments, the backside contact structure 360 is electrically connected to a backside metal line BM0 disposed on the back side 304 of the substrate 300, as shown in FIG. 13C. In such embodiments, the backside contact structure 360 may be electrically connected to power rails such as a Vdd line or a Vss line, as shown in FIG. 13C.

In some embodiments, the metal lines M0 of the BEOL interconnect structure on the front side 302 of the substrate 300 are signal lines, while the backside metal lines BM0 on the back side 304 of the substrate 300 are power rails. In such embodiments, the routing design is simplified when compared with comparative approaches that having both the signal lines and power rails on a same side.

In some embodiments, the backside contact structure 360 of the small CPP device has a depth greater than a depth of a backside contact structure (i.e., the contact structure 362) of the large CPP device. As mentioned above, the backside contact structure 360 may be referred to as a deeper (or taller) via that has more area coupled to the source/drain structure 316, and thus a contact resistance is reduced.

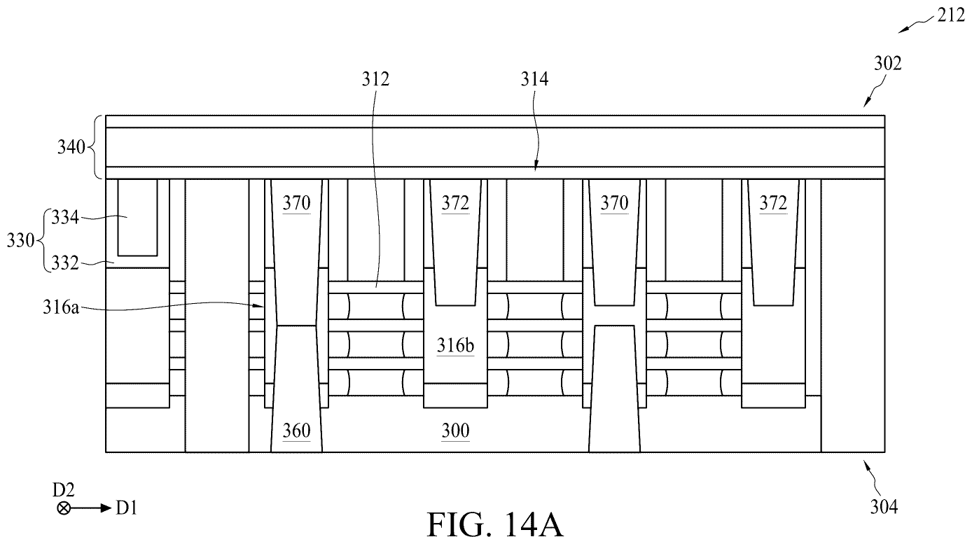

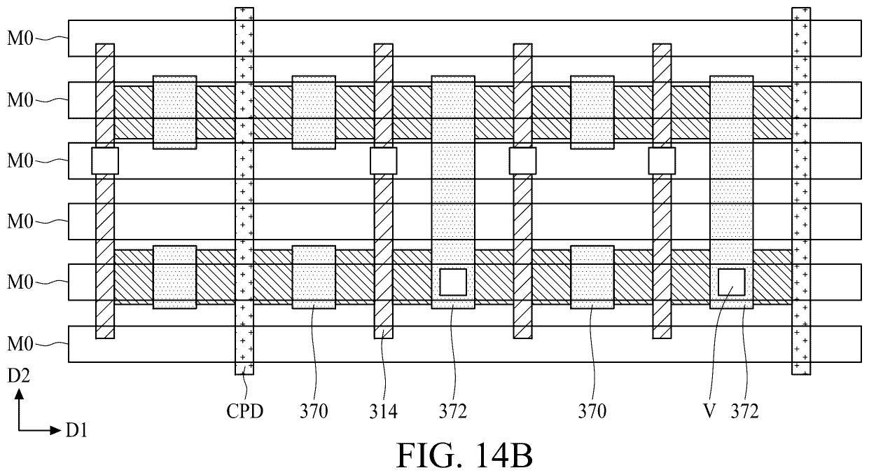

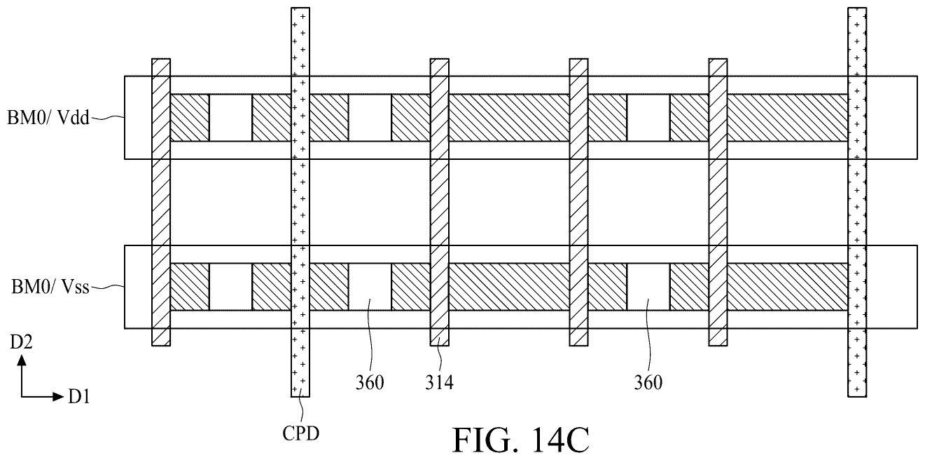

Please refer to FIG. 14A to 14C, wherein FIG. 14A is a cross-sectional view of a semiconductor structure in accordance with aspects of one or more embodiments of the present disclosure, FIG. 14B is a schematic layout structure from a top view of the semiconductor structure of FIG. 14A, and FIG. 14C, is a schematic layout structure from a bottom view of the semiconductor structure of FIG. 14A. In some embodiments, the semiconductor structure 212 is provided. The semiconductor structure 212 may include elements similar to those of the semiconductor structure 211; therefore, repeated descriptions are omitted. A difference between the semiconductor structure 211 and the semiconductor structure 212 is that, in the semiconductor structure 212, the contact structure 370 is in contact with the backside contact structure 360.

In some embodiments, in the semiconductor structure 212, the contact structure 370 is covered by the dielectric layer 340, and portions of sidewalls of the contact structure 370 are in contact with the dielectric structure 330. The contact structure 372 may be electrically connected to a metal line M0 disposed over the front side 302 of the substrate 300 through a via structure V, as shown in FIG. 14B. Further, the contact structures 372 are electrically connected to BEOL lines M0 through the via structure V. In some embodiments, the metal lines M0 are signal lines.

In some embodiments, the backside contact structure 360 is electrically connected to a backside metal line BM0 disposed on the back side 304 of the substrate 300, as shown in FIG. 14C. In such embodiments, the backside contact structure 360 may be electrically connected to power rails such as a Vdd line or a Vss line, as shown in FIG. 14C. In such embodiments, a contact area between the source/drain structure 316a and the contact structures (including the contact structure 370 and the backside contact structure 360) is increased, thereby further reducing the contact resistance.

In some embodiments, the metal lines M0 of the BEOL interconnect structure on the front side 302 of the substrate 300 are signal lines, while the backside metal lines BM0 on the back side 304 of the substrate 300 are power rails. In such embodiments, the routing design is simplified when compared with comparative approaches that having both the signal lines and power rails on a same side.

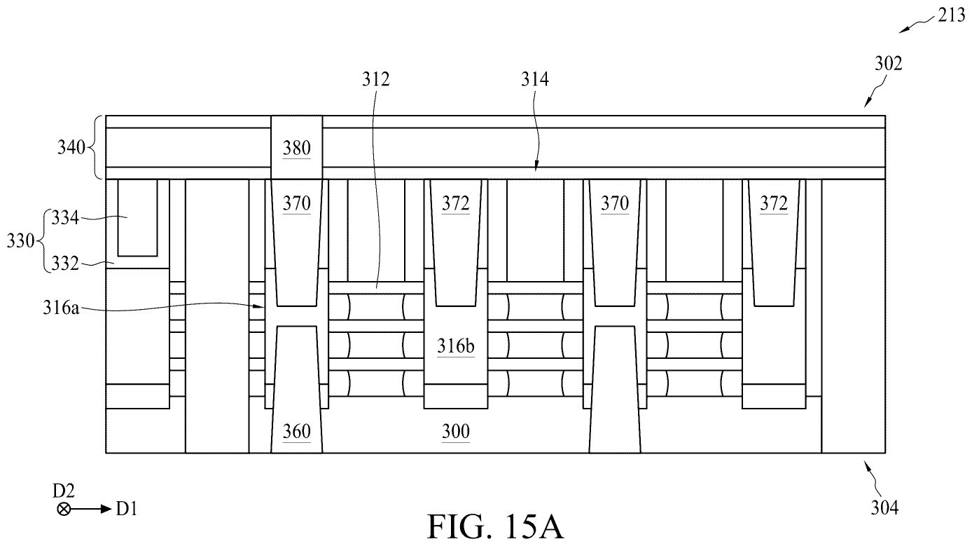

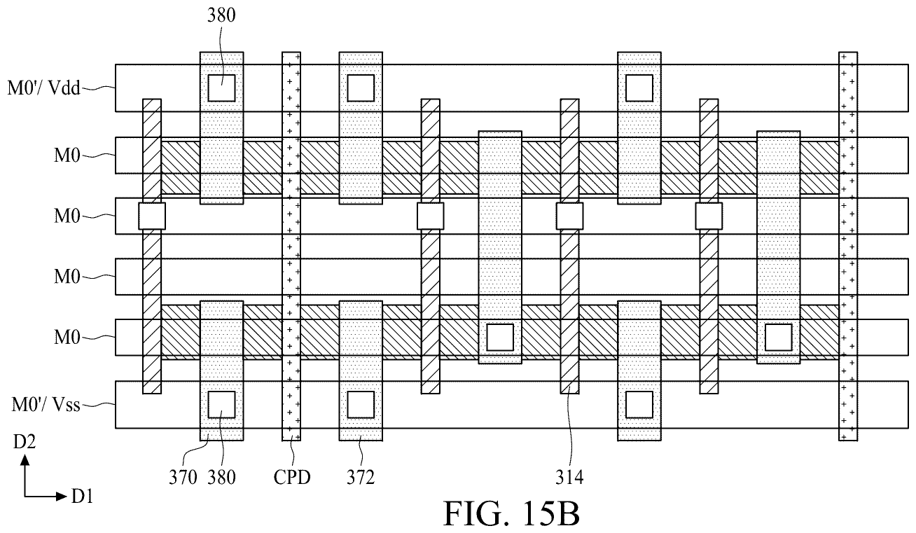

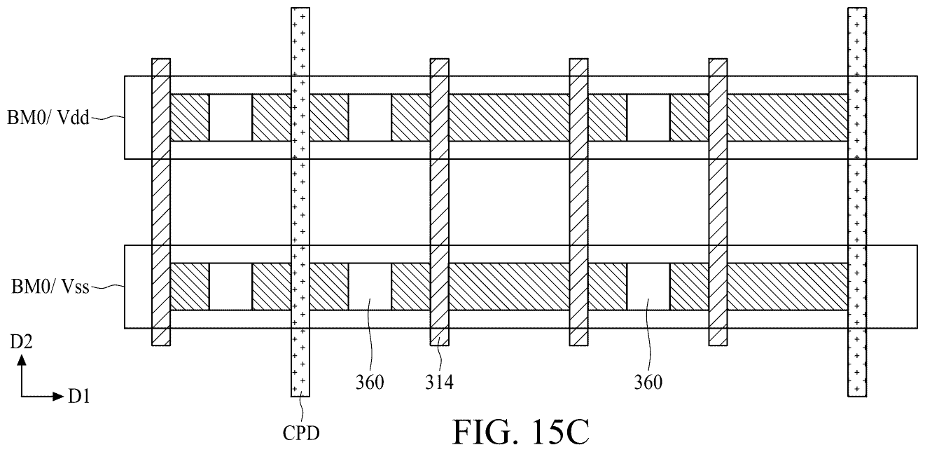

Please refer to FIGS. 15A to 15C, wherein FIG. 15A is a cross-sectional view of a semiconductor structure according to aspects of one or more embodiments of the present disclosure, FIG. 15B is a schematic layout structure from a top view of the semiconductor structure of FIG. 15A, and FIG. 15C is a schematic layout structure from a bottom view of the semiconductor structure of FIG. 15A. In some embodiments, the semiconductor structure 213 is provided. The semiconductor structure 213 may include elements similar to those of the semiconductor structure 211; therefore, repeated descriptions are omitted. A difference between the semiconductor structure 211 and the semiconductor structure 213 is that, in the semiconductor structure 213, the contact structure 370 is coupled to a via structure 380.

The contact structure 372 may be electrically connected to a metal line M0 disposed over the front side 302 of the substrate 300 through a via structure V, as shown in FIG. 15B. In some embodiments, the metal lines M0 are signal lines. In contrast with the contact structure 372, the contact structure 370 is electrically connected to another metal line M0′ through the via structure 380. In some embodiments, the metal line M0′ is a Vdd line or a Vss line. On the back side 304, the backside contact structure 360 is electrically connected to the backside metal lines BM0. In some embodiments, the backside metal line BM0 is a Vdd line or a Vss line. In such embodiments, the metal line M0′ and the backside metal line BM0 are equipotential. Accordingly, the contact structure 370 and the backside contact structure 360 are equipotential.

Please refer to FIG. 16, which is a cross-sectional view of a semiconductor structure in accordance with aspects of one or more embodiments of the present disclosure. In some embodiments, the semiconductor structure 214 is provided. The semiconductor structure 214 may include elements similar to those of the semiconductor structure 211; therefore, repeated descriptions are omitted. In some embodiments, the backside contact structure 360 may include a first portion 360-1 and a second portion 360-2 coupled to the first portion 360-1. The first portion 360-1 is coupled to the source/drain structure 316a, while the second portion 360-2 is separated from the source/drain structure 316a. Further, a width of the second portion 360-2 is greater than a width of the first portion 360-1. Accordingly, the backside contact structure 360 has a T-shaped (or an inverted T-shaped) configuration. In such embodiments, a parasitic resistance (R_{P}) is reduced.

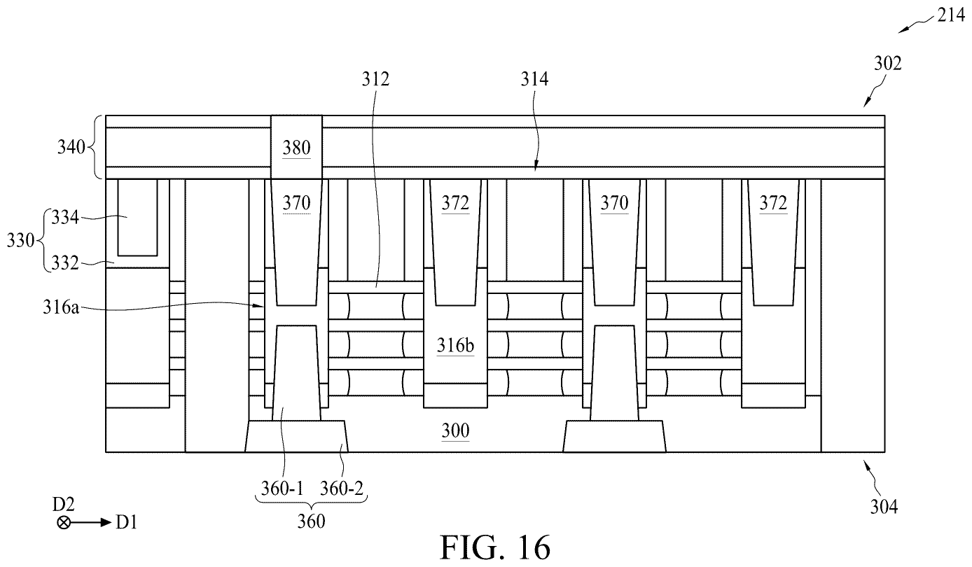

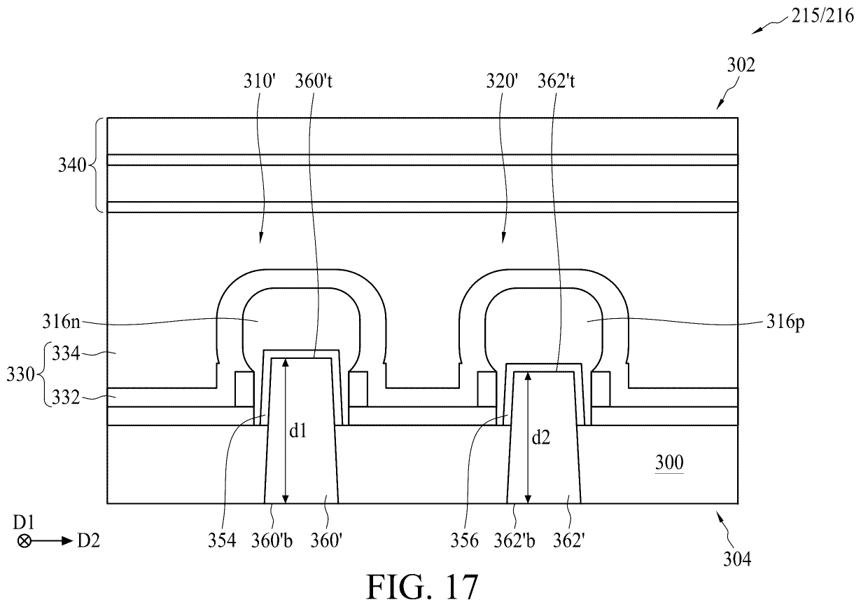

Please refer to FIG. 17, which is a cross-sectional view of a semiconductor structure in accordance with aspects of one or more embodiments of the present disclosure. In some embodiments, the semiconductor structure 215 is provided. The semiconductor structure 215 may be formed using the abovementioned method 10, but the disclosure is not limited thereto. In some embodiments, the semiconductor structure 215 may include a large CPP device 310′ and a small CPP device 320′. The large CPP device 310′and the small CPP device 320′ may be planar devices or non-planar devices. In some embodiments, when the large CPP device 310′and the small CPP device 320′ are non-planar devices, each of the large CPP device 310′ and the small CPP device 320′ can be a FinFET device or a GAA device. In some embodiments, the large CPP device 310′ and the small CPP device 320′ may have conductivity types that are complementary to each other. For example, the large CPP device 310′ may be an n-type FET device and the small CPP device 320′ may be a p-type FET device.

The semiconductor structure 215 includes a substrate 300 having a front side 302 and a back side 304 opposite to the front side 302. The substrate 300 may include materials similar to those described above; therefore, repeated descriptions are omitted herein. In some embodiments, both the large CPP device 310′ and the small CPP device 320′ of the semiconductor structure 215 are GAA devices. In such embodiments, each of the large CPP device 310′ and the small CPP device 320′ includes a plurality of nanostructure channels (not shown). Each of the large CPP device 310′ and the small CPP device 320′ further includes a gate structure (not shown) wrapped around the nanostructure channels. Further, the gate structure may include layers such as a high-k gate dielectric layer, a work function metal layer and a gap-filling layer that are similar to those described above; therefore, repeated descriptions are omitted. The nanostructure channels extend in a first direction D1, and the gate structure extends in a second direction D2 that is different from the first direction D1. The large CPP device 310′ further includes a source/drain structures 316n at two sides of its gate structure, and the small CPP device 320′ further includes a source/drain structure 316p at two sides of its gate structure.

In some embodiments, the semiconductor structure 215 further includes dielectric structures 330 and 340. The dielectric structures 330 and 340 may be similar to those described above; therefore, repeated descriptions are omitted.

In some embodiments, the semiconductor structure 215 further includes a backside contact structure 360′ and a backside contact structure 362′ extending in a direction perpendicular to both the first direction D1 and the second direction D2. The backside contact structure 360′ is extended from the back side 304 and coupled to the source/drain structure 316n, and the backside contact structure 362′ is extended from the back side 304 and coupled to the source/drain structure 316p. In some embodiments, formation of the backside contact structures 360′ and 362′ and materials of the contact structures 360′ and 362′ are similar to those of the abovementioned backside contact structures 360 and 362; therefore, repeated descriptions are omitted.

In some embodiments, a depth d1 of the backside contact structure 360′ is greater than a depth d2 of the backside contact structure 362′. In some embodiments, a width of the backside contact structure 360′ is less than a width of the backside contact structure 362′. The semiconductor structure 215 includes a silicide structure 354 between the source/drain structure 316n and the backside contact structure 360′, and a silicide structure 356 between the source/drain structure 316p and the backside contact structure 362′. In some embodiments, a surface area of the silicide structure 354 is greater than a surface area of the silicide structure 356.

In some embodiments, the depth d1 of the backside contact structure 360′ is measured from a topmost surface 360′t facing the front side 302 to a bottommost surface 360′b facing the back side 304, and the depth d2 of the backside contact structure 362′ is measured from a topmost surface 362′t facing the front side 302 to a bottommost surface 362′b facing the back side 304. In some embodiments, a difference between the depth d1 and the depth d2 may be between approximately 2 nanometers and approximately 10 nanometers, but the disclosure is not limited thereto.

As mentioned above, each of source/drain structure 316n and the source/drain structure 316p may have epitaxial structures. Still referring to FIG. 17, in such embodiments, a volume of the epitaxial source/drain structure 316p is greater than a volume of the epitaxial source/drain structure 316n, such that more stress can be provided to the p-type device.

Additionally, such design can be used in other large CPP devices. For example, in some embodiments, the first device 310′ and the second device 320′ are large CPP devices, wherein the first device 310′ is an n-type device and the second device 320′ is a p-type device. In such embodiments, the backside contact structure 360′ coupled to the source/drain structure of the n-type device 310′ is deeper than the backside contact structure 362′ coupled to the source/drain structure of the p-type device 320′. Accordingly, a volume of the epitaxial source/drain structure 316p of the p-type device 320′ is greater than a volume of the epitaxial source/drain structure 316n of the n-type device 310′, such that more stress can be provided to the p-type CPP device.

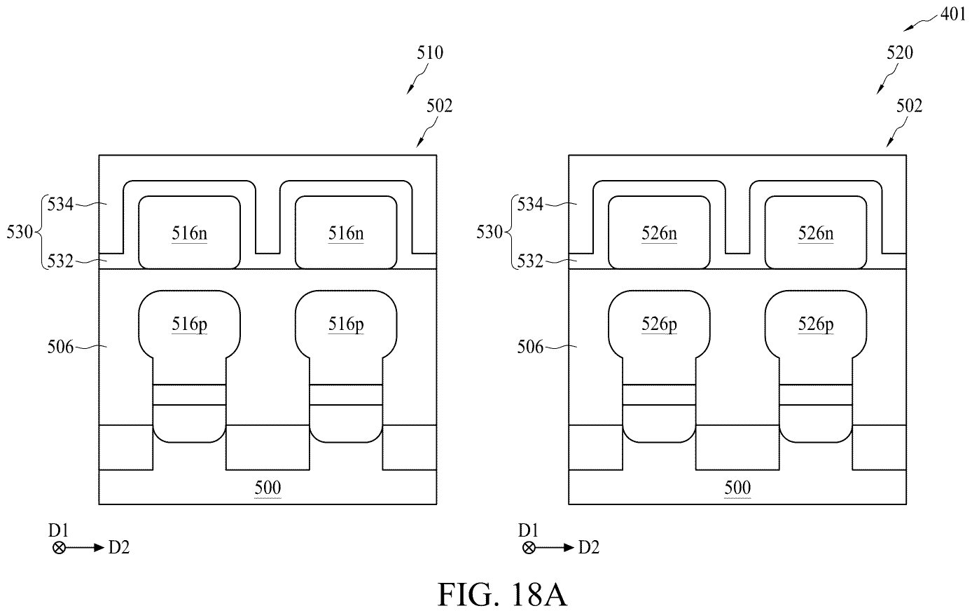

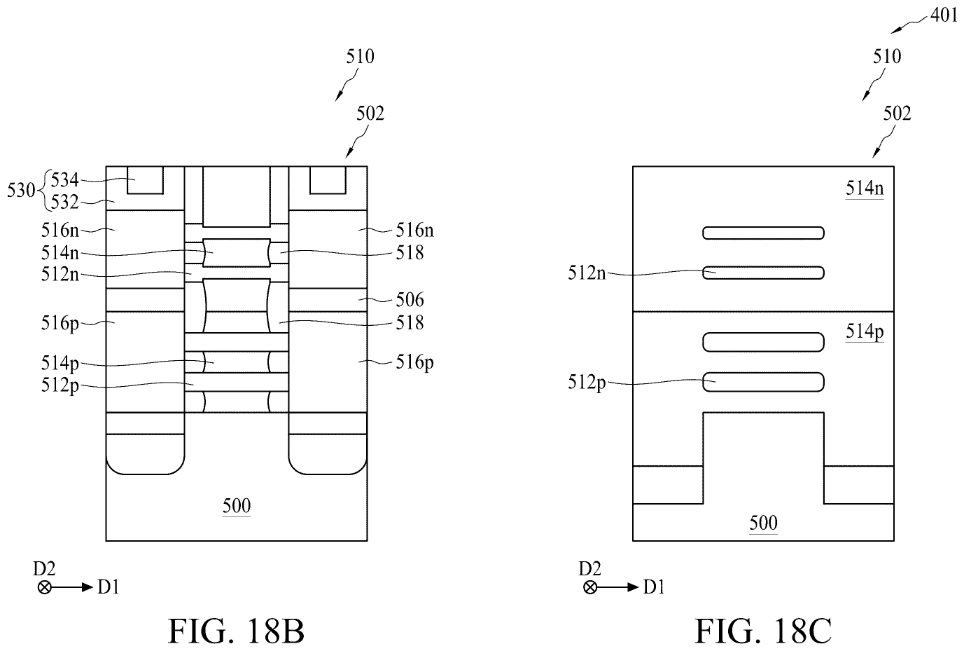

Please refer to FIGS. 18A to 26C, wherein FIG. 18A is a cross-sectional view of an intermediate semiconductor structure 401 at a fabrication stage according to aspects of one or more embodiments of the present disclosure, and FIGS. 18B and 18C are cross-sectional views of different portions of a small CPP device of FIG. 18A. In some embodiments, in operation 11, a substrate 500 including complementary field-effect transistor (CFET) devices formed thereon is received. In some embodiments, the substrate 5300 includes first CFET devices 510 and second CFET devices 520 disposed thereon. In some embodiments, each of the first CFET device 510 and the second CFET device 520 is a multi-gate device such as, for example but not limited thereto, a GAA FET device. Further, the first CFET device 510 is separated from the second CFET devices 520, as shown in FIG. 18A. In some embodiments, the first CFET device 510 and the second CFET device 520 may be separated from each other. In some embodiments, materials of the substrate 500 may be similar to those of the substrate 300; therefore, repeated descriptions are omitted. In some embodiments, the first CEFT devices 510 are small CPP devices, and the second CFET devices 520 are large CPP devices.

In some embodiments, the small CPP device 510 includes a plurality of nanostructure channels 512p of a p-type FET, and a plurality of nanostructure channels 512n of an n-type FET. Thicknesses of the nanostructure channels 512p and 512n are chosen based on device performance considerations. Further, the nanostructure channels 512p and 512n extend in a first direction D1, as shown in FIGS. 18B and 18C.

The small CPP device 510 further includes a gate structure 514p wrapped around the nanostructure channels 512p, and a gate structure 514n wrapped around the nanostructure channels 512n. The gate structure 514n overlaps the gate structure 514p, a shown in FIGS. 18B and 18C. In some embodiments, each of the gate structure 514p and the gate structure 514n may include at least a high-k gate dielectric layer, a work function metal layer and a gap-filling metal layer. In some embodiments, the high-k gate dielectric layers of the gate structure 514p and 514n may include a same material. In some embodiments, the gate structure 514p includes the work function metal layer of the p-type FET, and the gate structure 514n includes the work function metal layer of the n-type FET. In some embodiments, the gate structures 514p and 514n extend in a second direction D2. As shown in FIGS. 18A to 18C, the direction D2 is different from the direction D1.

The small CPP device 510 further includes a source/drain structure 516p disposed at two sides of the gate structure 514p, and a source/drain structure 516n disposed at two sides of the gate structure 514n. In some embodiments, the source/drain structure may be a source or a drain, individually or collectively depending upon the context. In some embodiments, the source/drain structure 516p and the source/drain structure 516n may be epitaxial source/drain structures. The epitaxial source/drain structure 516p includes dopants for the p-type FET, and the epitaxial source/drain structure 516n includes dopants for the n-type FET. In some embodiments, the epitaxial source/drain structures 516p and the epitaxial source/drain structure 516n serve as stressors. In some embodiments, the epitaxial source/drain structure 516n overlaps the epitaxial source/drain structure 516p. However, the source/drain structure 516p is separated from and isolated from the source/drain structure 516n by a dielectric layer 506, as shown in FIGS. 18A and 18B.

Additionally, the large CPP device 520 includes a plurality of nanostructure channels (not shown) for a p-type FET and an n-type FET, gate structures (not shown) for the p-type FET and the n-type FET, wherein the gate structures are wrapped around the respective nanostructure channels, and a source/drain structure 526p for the p-type FET and a source/drain structure 526n for the n-type FET. In some embodiments, the source/drain structure 526p and the source/drain structure 526n may be epitaxial source/drain structures. The epitaxial source/drain structure 526p includes dopants for the p-type FET, and the epitaxial source/drain structure 526n includes dopants for the n-type FET. In some embodiments, the epitaxial source/drain structure 526p and the epitaxial source/drain structure 526n serve as stressors. In some embodiments, the epitaxial source/drain structure 526n overlaps the epitaxial source/drain structure 526p. However, the source/drain structure 526p is separated from and isolated from the source/drain structure 526n by the dielectric layer 506, as shown in FIG. 18A.

Additionally, both the large CPP CFET devices 520 and the small CPP CFET devices 510 further includes a plurality of inner spacers 518. As shown in FIG. 18B, the inner spacers 518 are disposed between the source/drain structure 516p and the gate structure 514p, and between the source/drain structure 516n and the gate structure 514n.

In some embodiments, a dielectric structure 530 is formed over the substrate 500. In some embodiments, the dielectric structure 530 includes a CESL 532 and an ILD 534. In some embodiments, materials of the CESL 532 may be similar to those of the CESL 332, and materials of the ILD 534 may be similar to those of the ILD 334; therefore, repeated descriptions are omitted herein.

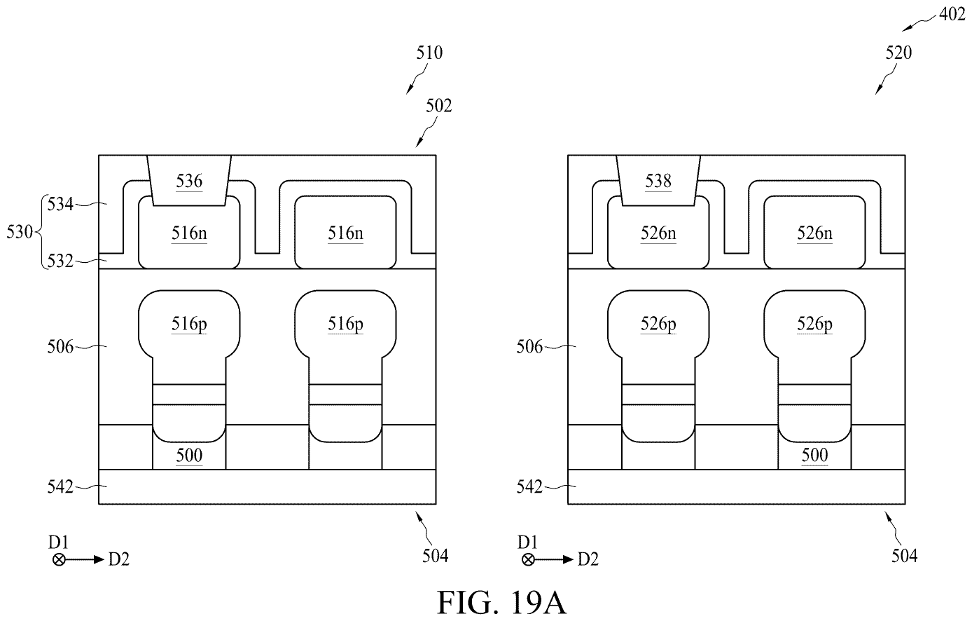

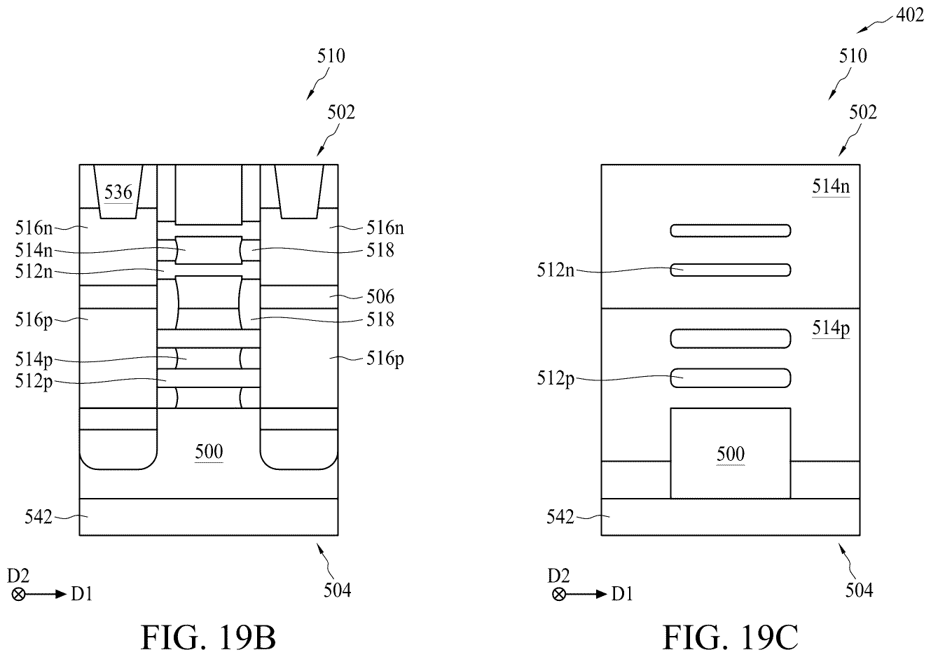

Referring to FIGS. 19A to 19C, in some embodiments, contact structures may be formed to couple to the source/drain structures from a front side 502 of the substrate 500. For example, a contact structure 536 is formed to couple to the source/drain structure 516n of the FET device of the small CPP device 510, and a contact structure 538 is formed to couple to the source/drain structure 526n of the FET device of the large CPP device 520. In some embodiments, metal silicide structures may be formed between the contact structure 536 and the source/drain structure 516n, and between the contact structure 538 and the source/drain structure 526n, though not shown. In some embodiments, a depth of the contact structure 536 and a depth of the contact structure 538 may be the same, but the disclosure is not limited thereto. In some embodiments, a width of the contact structure 536 and a width of the contact structure 538 may be the same, but the disclosure is not limited thereto. In some alternative embodiments, the width of the contact structure 536 is less than the width of the contact structure 538.

In some embodiments, in operation 12, a first recess is formed on a back side 504 of the substrate 500. In some embodiments, operation 12 may include further operations. Still referring to FIGS. 19A to 19C, in some embodiments, a portion of the substrate 500 is removed from the back side 504. Subsequently, a dielectric layer 542 is formed over the substrate 500 on the back side 504. In some embodiments, the dielectric layer 542 includes a single-layered structure or a multi-layered structure. In some embodiments, the dielectric layer 542 may include a material similar as that of the dielectric layer 342; therefore, repeated descriptions are omitted herein. The dielectric layer 542 may serve as a bottom isolation for mitigating a bottom leakage issue.

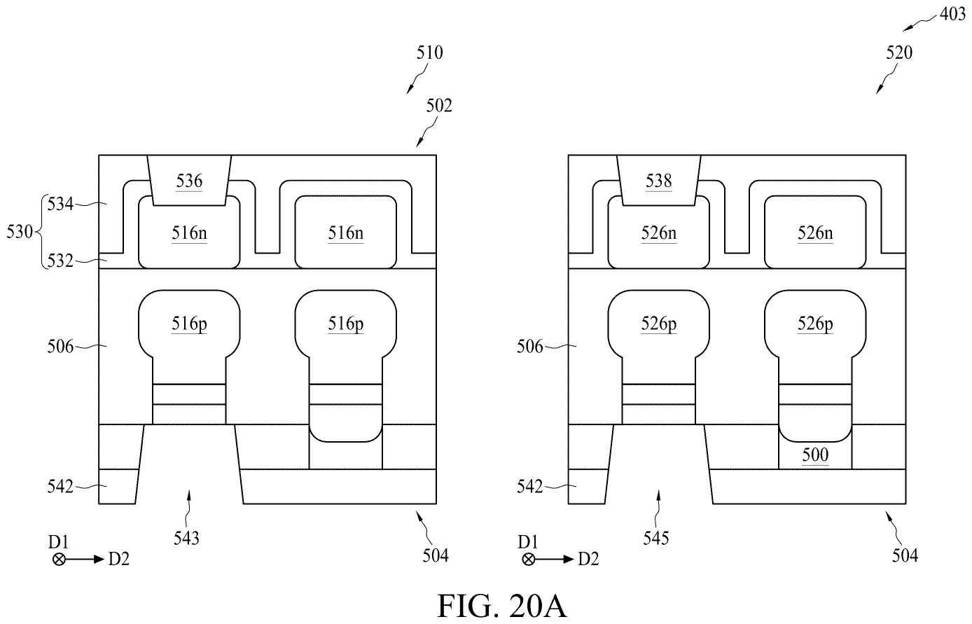

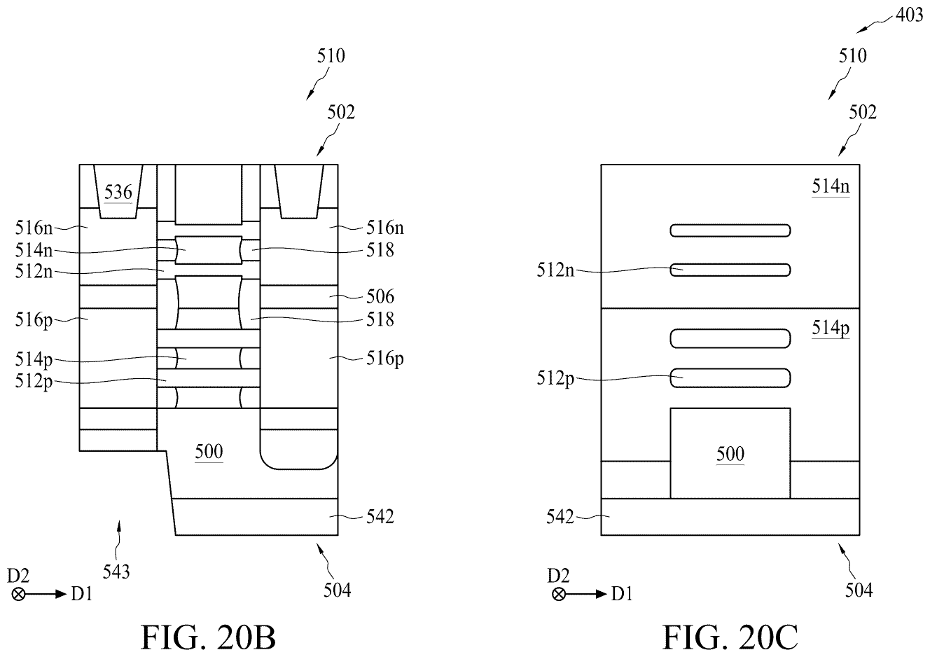

Please refer to FIGS. 20A to 20C, wherein FIGS. 20A to 20C are cross-sectional views of an intermediate semiconductor structure 403 at a fabrication stage subsequent to that shown in FIGS. 19A to 19C in accordance with aspects of one or more embodiments of the present disclosure. In some embodiments, a patterned mask (not shown) may be formed over the substrate 500 on the back side 504. Subsequently, an etch operation is performed to remove portions of the dielectric layer 542 and portions of the substrate 500 from the back side 504. Accordingly, recesses 543 and 545 are formed. As shown in FIGS. 20A and 20B, a portion of the source/drain structure 516p is exposed through the recess 543 on the back side 504, and a portion of the source/drain structure 526p is exposed though the recess 545 on the back side 504. In some embodiments, a depth of the recess 543 is equal to a depth of the recess 545. In some embodiments, a width of the recess 543 is equal to a width of the recess 545. In some embodiments, when the source/drain structure 526p has a greater volume for a large CPP device (i.e., the second FET device), the width of the recess 545 may be greater than the width of the recess 543.

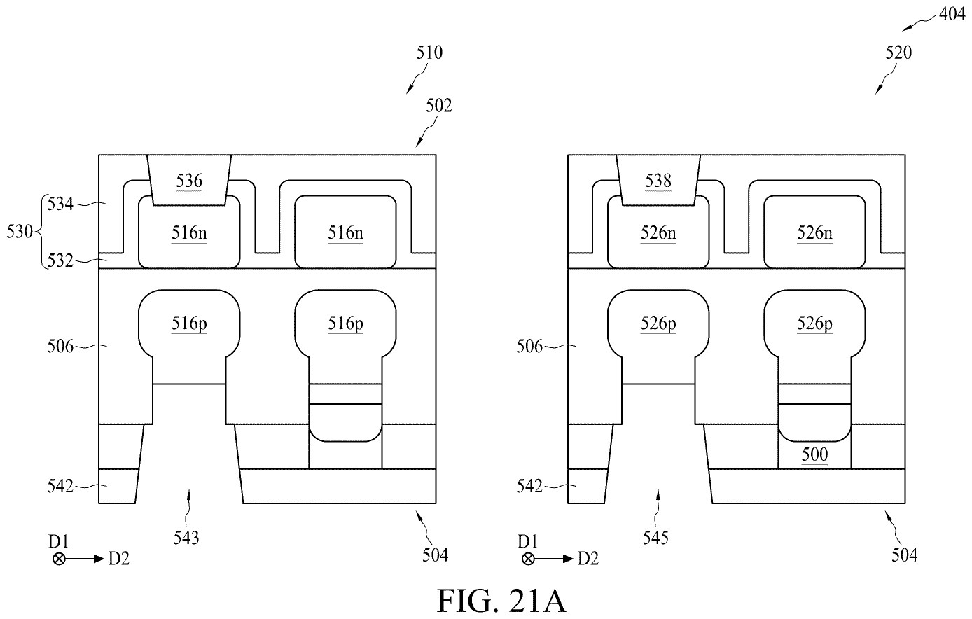

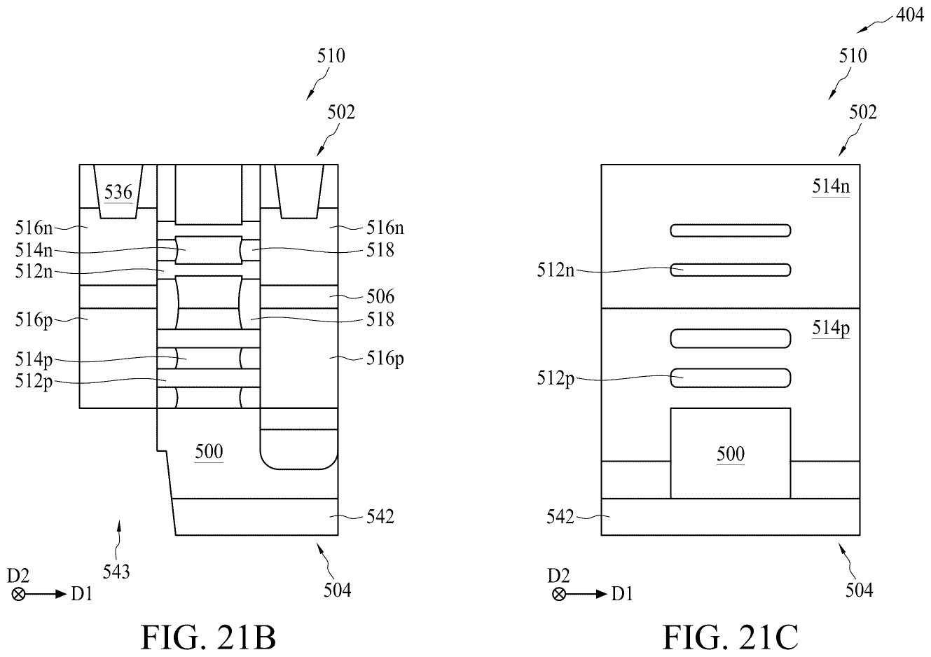

Please refer to FIGS. 21A to 21C, wherein FIGS. 21A to 21C are cross-sectional views of an intermediate semiconductor structure 404 at a fabrication stage subsequent to that shown in FIGS. 20A to 20C in accordance with aspects of one or more embodiments of the present disclosure. In some embodiments, a portion of the source/drain structure 516p exposed through the recess 543 is removed, and a portion of the source/drain structure 526p exposed through the recess 545 is removed. For example, when the source/drain structures 516p and 526p include an epitaxial layer that includes a non-doped semiconductor material, such epitaxial layers of the source/drain structure 516p and the source/drain structure 526p are removed.

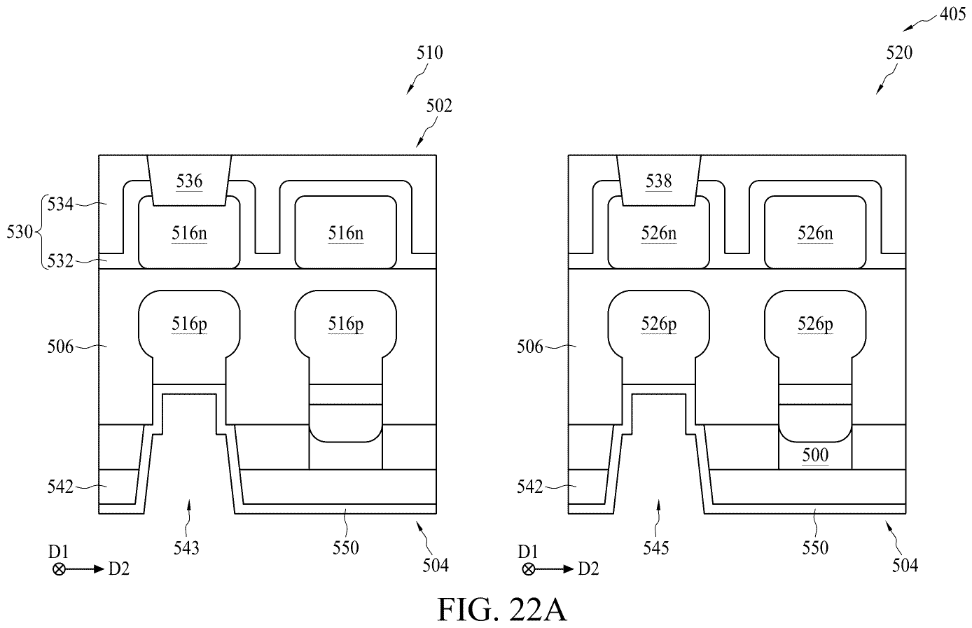

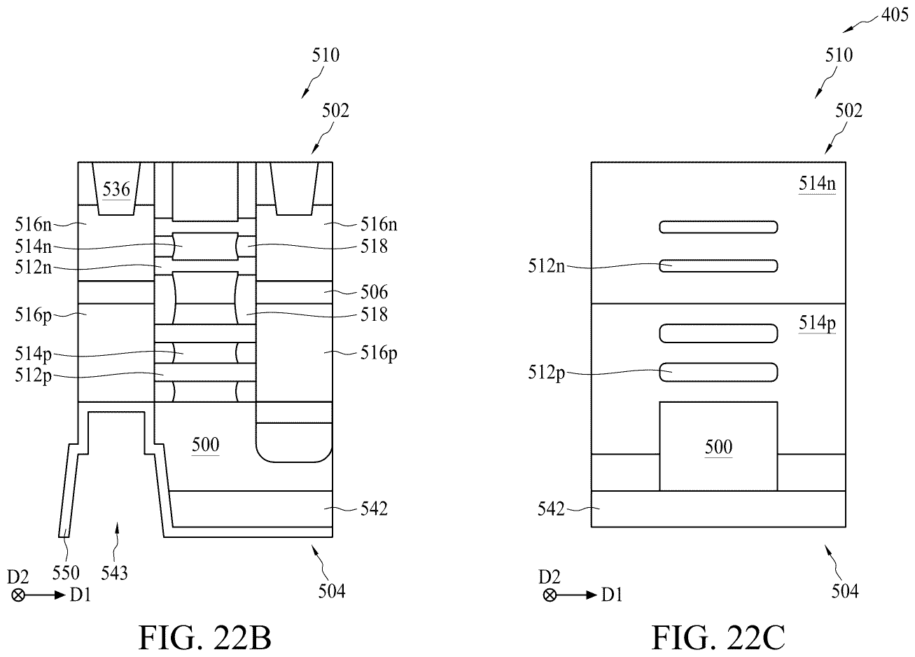

Please refer to FIGS. 22A to 22C, wherein FIGS. 22A to 22C are cross-sectional views of an intermediate semiconductor structure 405 at a fabrication stage subsequent to that shown in FIGS. 21A to 21C in accordance with to aspects of one or more embodiments of the present disclosure. In some embodiments, a dielectric layer 550 may be formed over the substrate 500 on the back side 504. The dielectric layer 550 covers sidewalls of the recess 543, sidewalls of the recess 545, and the dielectric layer 542. Further, the dielectric layer 550 covers the portion of the source/drain structure 516p exposed through the recess 543, and the portion of the source/drain structure 526p exposed through the recess 545. In some embodiments, the dielectric layer 550 includes SiN. In such embodiments, the dielectric layer 550 may be referred to as an SNR layer, but the disclosure is not limited thereto.

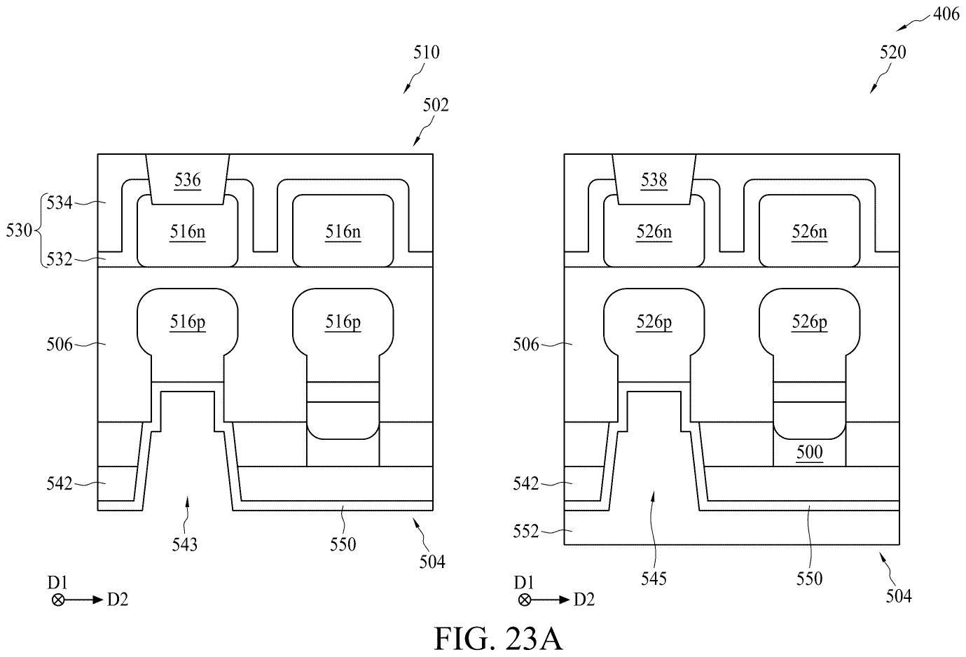

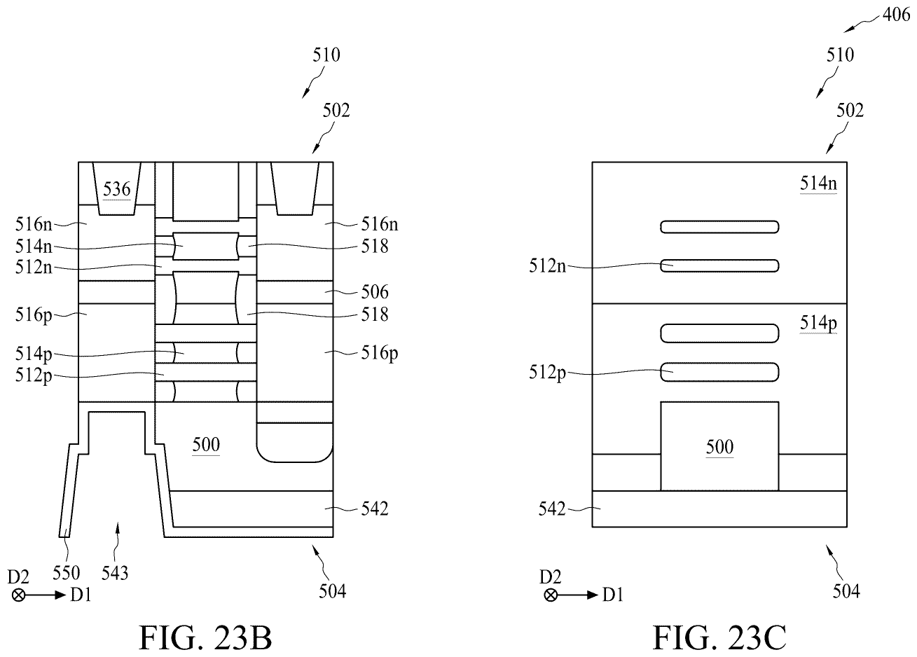

Please refer to FIGS. 23A to 23C, wherein FIGS. 23A to 23C are cross-sectional views of an intermediate semiconductor structure 406 at a fabrication stage subsequent to that shown in FIGS. 22A to 22C in accordance with aspects of one or more embodiments of the present disclosure. In some embodiments, a protection layer 552 is formed to fill the recess 545 and covers a portion of the dielectric layer 550 in an area where the large CPP device 520 is located. In some embodiments, the protection layer 552 may include a photoresist and/or a BARC, but the disclosure is not limited thereto.

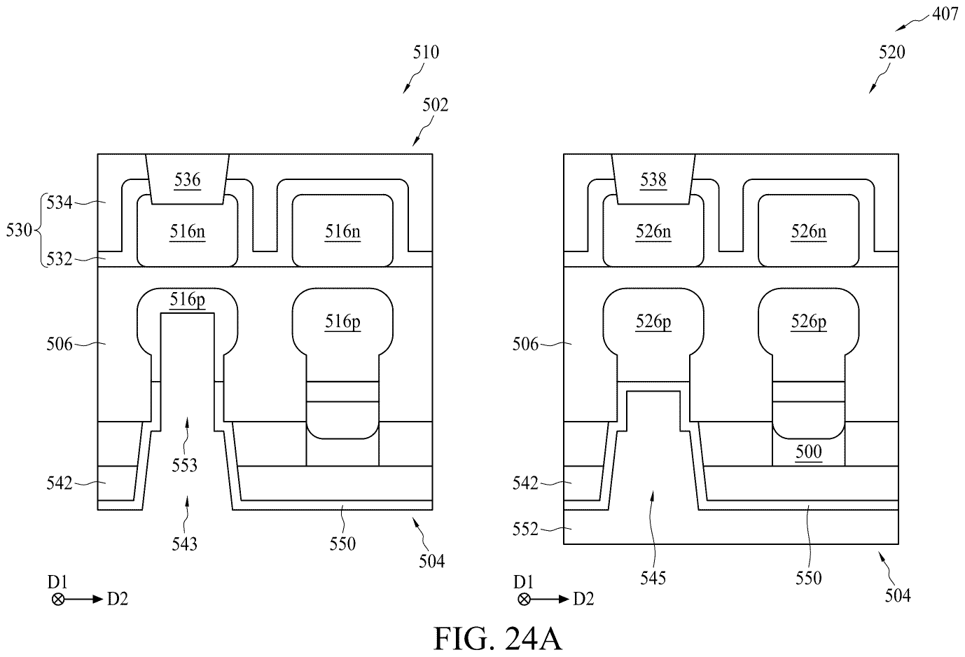

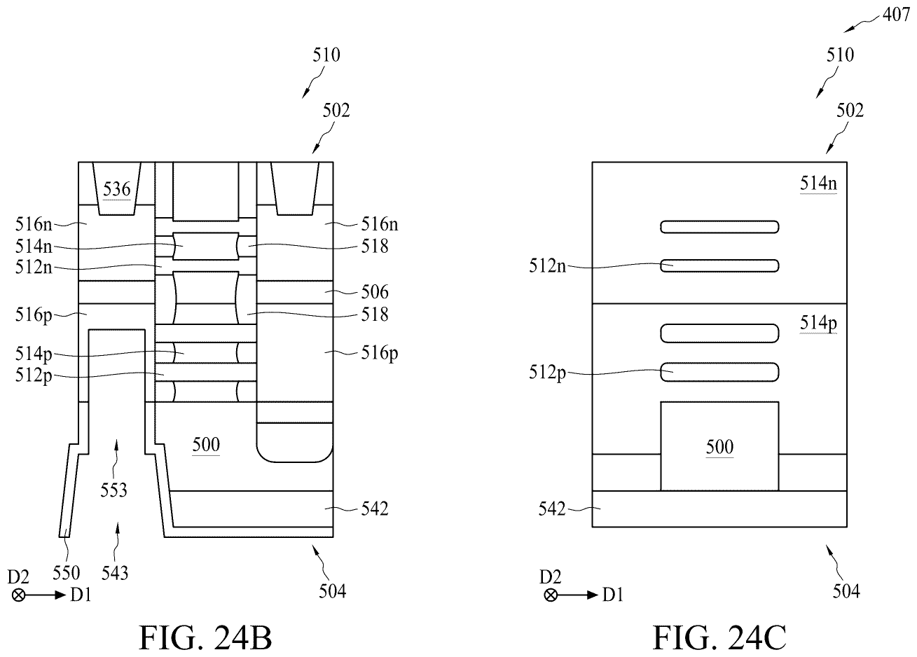

Please refer to FIGS. 24A to 24C, wherein FIGS. 24A to 24C are cross-sectional views of an intermediate semiconductor structure 407 at a fabrication stage subsequent to that shown in FIGS. 23A to 23C in accordance with aspects of one or more embodiments of the present disclosure. In some embodiments, the protection layer 552 may serve as a mask layer in an etch operation. For example, in some embodiments, a portion of the dielectric layer 550 exposed through the mask layer (i.e., the protection layer 552) is removed by the etch operation. Consequently, the source/drain structure 516p is exposed through the recess 543 again. In some embodiments, in operation 13, a portion of the source/drain structure 516p exposed through the recess 543 is removed such that a recess 553 is formed. As shown in FIGS. 24A and 24B, the recess 553 is coupled to the recess 543. In some embodiments, the remaining source/drain structure 516p may have a first surface facing the front side 502, and a second surface facing the back side 504 and exposed through the recess 553. In some embodiments, the second surface of the remaining source/drain structure 516p is lower than a topmost nanostructure channel 512p, as shown in FIG. 24B.

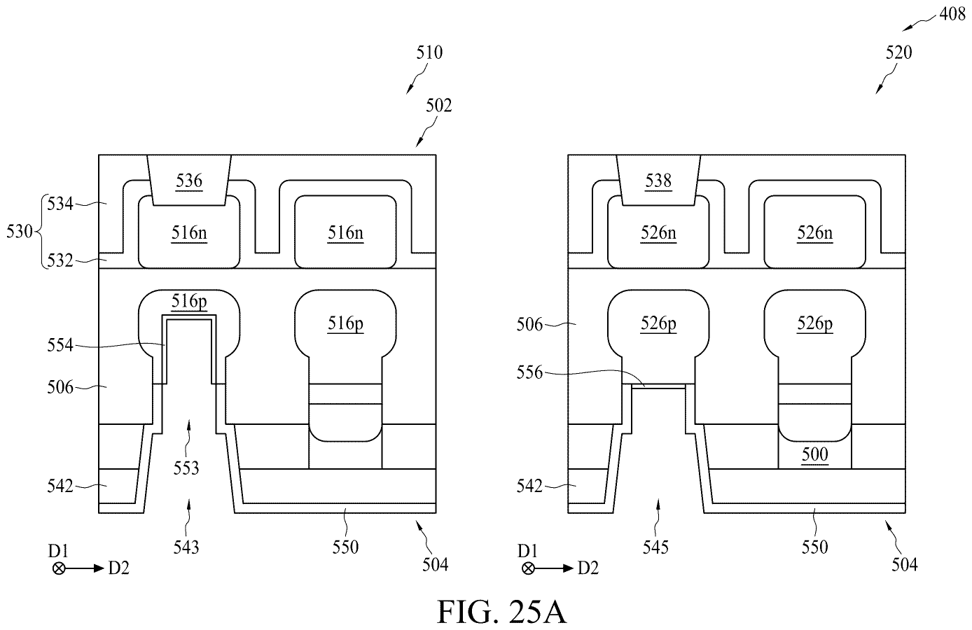

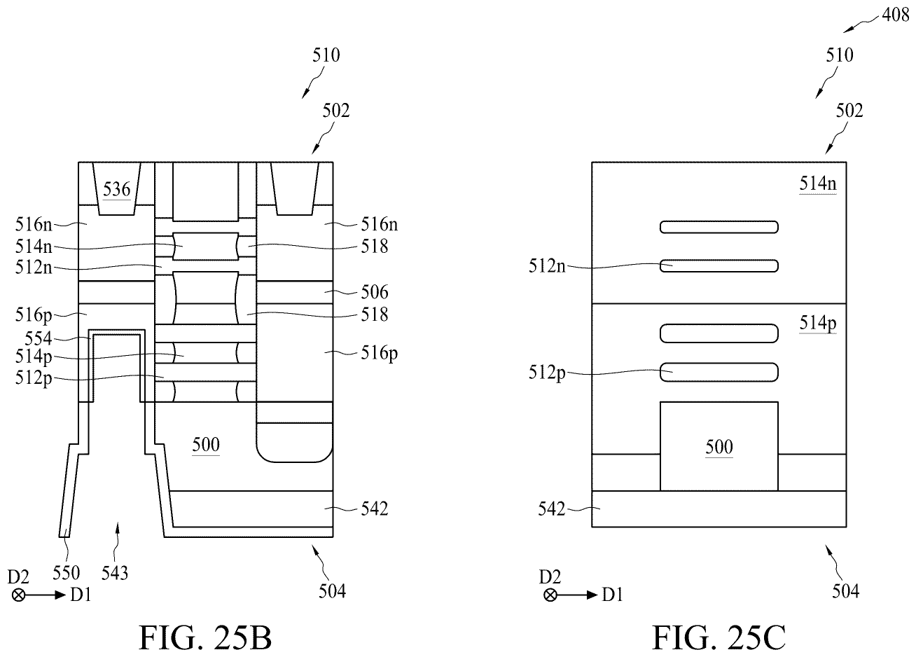

In some embodiments, in operation 14, a contact structure is formed in the recesses 543 and 553. In some embodiments, operation 14 includes further operations. Please refer to FIGS. 25A to 25C, wherein FIGS. 25A to 25C are cross-sectional views of an intermediate semiconductor structure 408 at a fabrication stage subsequent to that shown in FIGS. 24A to 24C in accordance with aspects of one or more embodiments of the present disclosure. In some embodiments, the protection layer 552 is removed, and a portion of the dielectric layer 550 is subsequently removed, thereby exposing a portion of the source/drain structure 526p through the recess 545. In some embodiments, metal silicide structures 554 and 556 are formed. As shown in FIG. 25A, the metal silicide structure 554 is formed over surfaces of the source/drain structure 516p exposed through the recess 553, and the metal silicide structure 556 is formed over a surface of the source/drain structure 526p exposed through the recess 545. In some embodiments, a configuration of the metal silicide structure 554 is different from a configuration of the metal silicide structure 556. For example but not limited thereto, the metal silicide structure 554 has a U-shaped (or an inverted U-shaped) configuration, while the metal silicide structure 556 has a flat configuration.

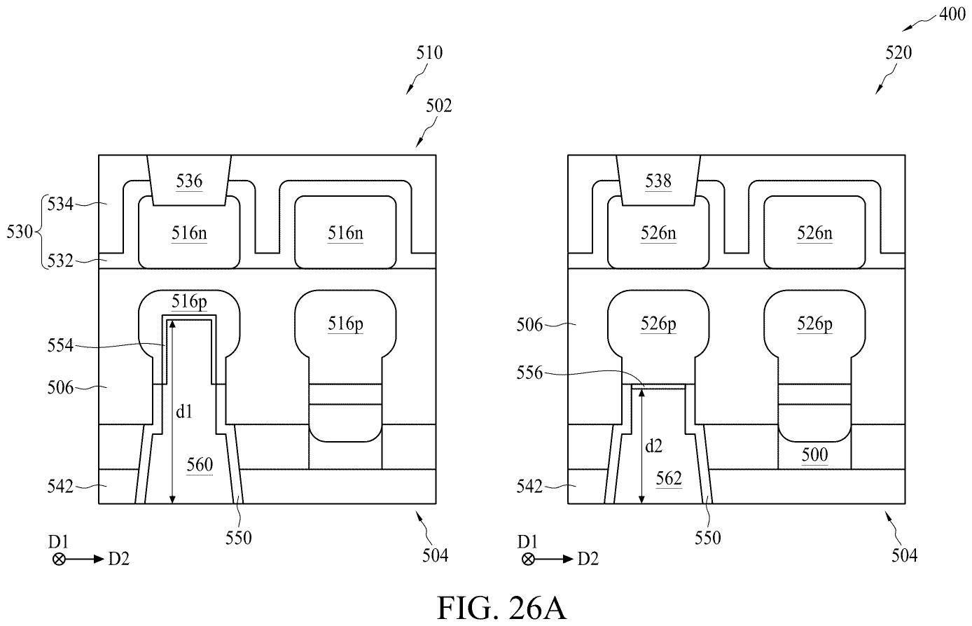

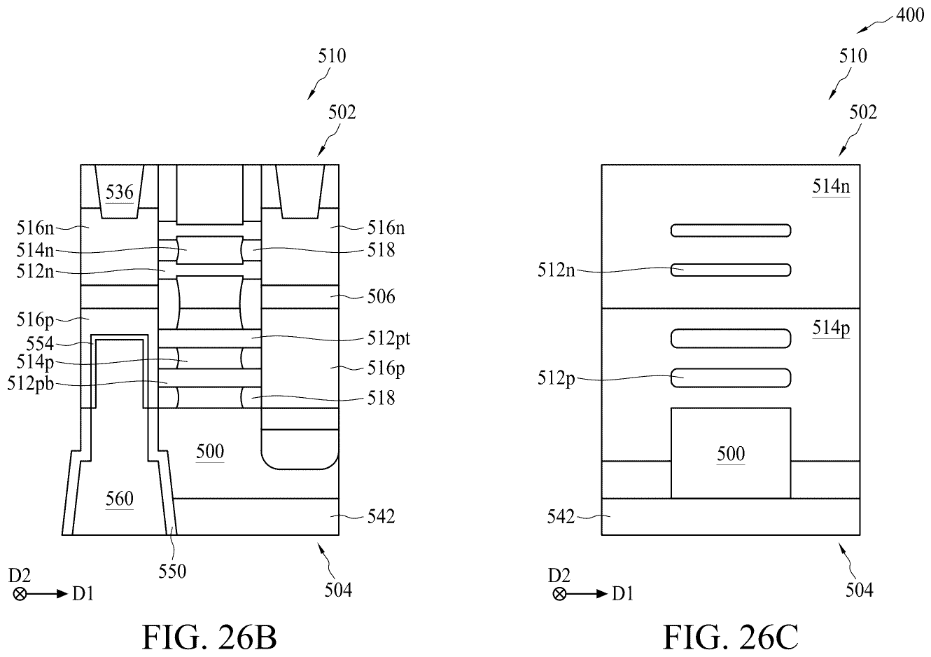

Please refer to FIGS. 26A to 26C, wherein FIGS. 26A to 26C are cross-sectional views of a semiconductor structure 400 at a fabrication stage subsequent to that shown in FIGS. 25A to 25C in accordance with aspects of one or more embodiments of the present disclosure. In some embodiments, a backside contact structure 560 is formed in the recesses 543 and 553, and a backside contact structure 562 is formed in the recess 545. In some embodiments, the backside contact structures 560 and 562 include a same material.

Accordingly, the semiconductor structure 400 is provided. The semiconductor structure 400 includes a substrate (i.e., the substrate 500), a first CFET device (i.e., the small CPP device 510) and a second CFET device (i.e., the large CPP device 520). Details of the small CPP device 510 and the large CPP device 520 may be similar to those described above; therefore, repeated descriptions are omitted. In some embodiments, a width of the gate structures 524p and 524n of the large CPP device 520 is greater than a width of the gate structures 514p and 515n of the small CPP device 510.

Still referring to FIGS. 26A to 26C, the semiconductor structure 400 further includes a backside contact structure 560 and a backside contact structure 562 penetrating the substrate 500 from the back side 504. The backside contact structure 560 is coupled to the source/drain structure 516p, and the backside contact structure 562 is coupled to the source/drain structure 526p. In some embodiments, a depth d1 of the backside contact structure 560 is measured from a topmost surface facing the front side 502 to a bottommost surface facing the back side 504, and a depth d2 of the backside contact structure 562 is measured from a topmost surface facing the front side 502 to a bottommost surface facing the back side 504. As shown in FIG. 26A, the depth d1 of the backside contact structure 560 is greater than the depth d2 of the backside contact structure 562. In some embodiments, a difference between the depth d1 and the depth d2 may be between approximately 2 nanometers and approximately 25 nanometers, but the disclosure is not limited thereto.

Referring to FIG. 26B, in some embodiments, the top surface of the backside contact structure 560 is between a bottommost nanostructure channel 512pb and a topmost nanostructure channel 512pt. In some embodiments, a width of the backside contact structure 560 may be less than a width of the backside contact structure 562. In some embodiments, a difference between the width of the backside contact structure 562 and the width of the backside contact structure 560 is between approximately 1 nanometer and approximately 10 nanometers, but the disclosure is not limited thereto. In some embodiments, the backside contact structure 560 is referred to as a deeper (or taller) structure, and the contact structure 562 is referred to as a shallower (or shorter) structure. In some embodiments, the small CPP device 510 has the deeper backside contact structure 560 while the large CPP device 520 has the shallower backside contact structure 562. The deeper backside contact structure 560 has more area coupled to the source/drain structure 516p, and thus a contact resistance is reduced.

Accordingly, the present disclosure therefore provides a semiconductor structure and a method for forming the same. In some embodiments, a contact structure for smaller CPP devices has a thickness or a depth greater than that of a contact structure for larger CPP devices. In some embodiments, the contact structure for the smaller CPP devices has a width less than a width of the contact structure for the larger CPP devices. Accordingly, contact resistance for the smaller CPP devices is reduced, and thus device performance of the smaller CPP devices and the larger CPP devices can be improved concurrently.

According to one embodiment of the present disclosure, a semiconductor structure is provided. The semiconductor structure includes a substrate, a first device, a second device, a first contact structure and a second contact structure. The first device includes a first gate structure and a first source/drain structure, and the second device includes a second gate structure and a second source/drain structure. The first contact structure penetrates the substrate from a back side and is coupled to the first source/drain structure. The second contact structures penetrates the substrate from the back side and is coupled to the second source/drain structure. A contacted poly pitch of the second gate structure is greater than a contacted poly pitch of the first gate structure, and a depth of the first contact structure is greater than a depth of the second contact structure.

According to one embodiment of the present disclosure, a semiconductor structure is provided. The semiconductor structure includes gate structure over a substrate, a source/drain structure at a side of the gate structure, a first contact structure, and a second contact structure. The first contact structure penetrates the substrate from a back side in a vertical direction, and is coupled to the source/drain structure. The second contact structure extended in the vertical direction from a front side, and is coupled to the source/drain structure.

According to one embodiment of the present disclosure, a method for forming a semiconductor structure is provided. The method includes following operations. A substrate is received. The substrate includes at least a first FET device formed thereon. The first FET device includes a first gate structure and a first source/drain structure. A first recess is formed on a back side of the substrate. A portion of the first source/drain structure is exposed through the first recess. The portion of the first source/drain structure exposed through the first recess is removed to form a second recess. A first contact structure is formed in the first recess and the second recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a substrate;
a first device comprising a first gate structure and a first source/drain structure;
a second device comprising a second gate structure and a second source/drain structure;
a first contact structure penetrating the substrate from a back side of the substrate and coupled to the first source/drain structure; and
a second contact structure penetrating the substrate from the back side and coupled to the second source/drain structure,
wherein a contacted poly pitch of the second gate structure is greater than a contacted poly pitch of the first gate structure, and a depth of the first contact structure is greater than a depth of the second contact structure.

2. The semiconductor structure of claim 1, wherein a width of the first contact structure is less than the width of the second contact structure.

3. The semiconductor structure of claim 1, wherein a width of the second gate structure is greater than a width of the first gate structure.

4. The semiconductor structure of claim 1, further comprising a third device over the first device, wherein the third device is an n-type FET device, and the second device is a p-type FET device.

5. The semiconductor structure of claim 4, wherein the third device comprises a third gate structure over the first gate structure and a third source/drain structure over the first source/drain structure, and wherein the third source/drain structure is separated from the first source/drain structure.

6. The semiconductor structure of claim 5, further comprising a third contact structure coupled to the third source/drain structure, wherein the third contact structure overlaps at least a portion of the first contact structure, and the third contact structure is separated from the first contact structure.

7. A semiconductor structure comprising:
a gate structure over a substrate;
a source/drain structure at a side of the gate structure;
a first contact structure penetrating the substrate from a back side in a vertical direction and coupled to the source/drain structure; and
a second contact structure extending in the vertical direction from a front side and coupled to the source/drain structure.

8. The semiconductor structure of claim 7, wherein the second contact structure overlaps the first contact structure.

9. The semiconductor structure of claim 7, wherein the first contact structure is in contact with the second contact structure.

10. The semiconductor structure of claim 7, wherein the first contact structure and the second contact structure are separated from each other.

11. The semiconductor structure of claim 10, further comprising:
a first power rail disposed over the back side of the substrate; and
a second power rail disposed over the front side of the substrate,
wherein the first contact structure is electrically connected to the first power rail.

12. The semiconductor structure of claim 11, wherein the second contact structure is electrically isolated.

13. The semiconductor structure of claim 11, wherein the second contact structure is electrically connected to the second power rail.

14. The semiconductor structure of claim 13, wherein the first power rail and the second power rail are equipotential.

15. The semiconductor structure of claim 7, wherein the first contact structure comprises:
a first portion coupled to the source/drain structure; and
a second portion separated from the source/drain structure,
wherein a width of the first portion is less than a width of the second portion.

16. A method for forming a semiconductor structure, comprising:
receiving a substrate comprising at least a first field-effect transistor (FET) device formed thereon, wherein the first FET device comprises a first gate structure and a first source/drain structure;
forming a first recess on a back side of the substrate, wherein a portion of the first source/drain structure is exposed through the first recess;
removing portion of the first source/drain structure to form a second recess coupled to the first recess; and
forming a first contact structure in the first recess and the second recess.

17. The method of claim 16, wherein the substrate further comprises a second FET device, wherein the second FET device comprises a second gate structure and a second source/drain structure, and a width of the second gate structure is greater than a width of the first gate structure.

18. The method of claim 17, further comprising forming a third recess on the back side of the substrate simultaneously with the forming of the first recess, wherein a portion of the second source/drain structure is exposed through the third recess.

19. The method of claim 18, further comprising forming a protection layer in the third recess prior to the forming of the second recess.

20. The method of claim 16, further comprising forming a dielectric layer over sidewalls of the first recess.
